(19) United States
(12) Patent Application Publication
(10) Pub. No.: US 2026/0372094 A1
(43) Pub. Date: Nov. 19, 2026

(54) SEMICONDUCTOR DEVICE

(71) Applicant: Samsung Electronics Co., Ltd., Suwon-si (KR)

(72) Inventors: Jaehoon Shin, Suwon-si (KR); Jeewoong Kim, Suwon-si (KR); Jinkyu Kim, Suwon-si (KR); Yunsuk Nam, Suwon-si (KR); Yongwoo Lee, Suwon-si (KR); Yunju Cho, Suwon-si (KR)

(73) Assignee: Samsung Electronics Co., Ltd., Suwon-si (KR)

(21) Appl. No.: 19/385,831

(22) Filed: Nov. 11, 2025

(30) Foreign Application Priority Data
May 19, 2025 (KR) 10-2025-0064433

(51) Int. Cl. H10W 42/00; H10D 30/00; H10D 30/01; H10D 64/23

(52) U.S. Cl. CPC H10W 42/00; H10D 30/0198; H10D 30/501; H10D 64/254; H10W 42/121

(57) ABSTRACT

A semiconductor device includes a substrate including a central region and a peripheral region surrounding the central region, a guard structure disposed in the peripheral region and including a first surface and a second surface opposite to the first surface, a frontside guard wiring structure disposed on the first surface of the guard structure, and a backside guard wiring structure disposed on the second surface of the guard structure, wherein the guard structure includes a connection via pattern connected to the backside guard wiring structure and extending in a first direction substantially perpendicular to a surface of the substrate by penetrating the substrate, and a first width of the connection via pattern at a first vertical level may be greater than a second width of the connection via pattern at a second vertical level.

### CROSS-REFERENCE TO RELATED APPLICATIONS

This present application claims priority to and the benefit under 35 U.S.C. § 119(a)-(d) of Korean Patent Application No. 10-2025-0064433, filed on May 19, 2025, in the Korean Intellectual Property Office, the entire disclosure of which is incorporated herein by reference.

### FIELD

The present disclosure relates to a semiconductor device.

### BACKGROUND

A semiconductor device may be used as a component of an electronic device for storing data or controlling electrical signals, and various types of semiconductor devices may be manufactured for this purpose. For example, a memory device may be mainly used for storing and retrieving data, whereas a non-memory device may be used for controlling or amplifying electrical signals. As a core component of electronic devices, such a semiconductor device is used in various fields of computers, communication equipment, or consumer electronic products.

With the advancement of technology, the demands for the functions of electronic devices are continuously increasing. To meet these demands, it is essential not only to improve the integration density of semiconductor devices but also to secure high reliability. In particular, it is important to protect a semiconductor device region from vibrations that occur during a wafer dicing process or from moisture that may be introduced during a process. For this purpose, various structures for protecting the device region may be applied to the semiconductor device.

### SUMMARY

The present disclosure aims to provide a semiconductor device with improved reliability and/or electrical performance.

The problems to be solved by the present disclosure are not limited to those mentioned above, and other unmentioned problems can be clearly understood by those of ordinary skill in the art from the description of the disclosure below.

According to some embodiments of the present disclosure, a semiconductor device includes a substrate including a central region and a peripheral region surrounding the central region, a guard structure disposed in the peripheral region and including a first surface and a second surface opposite to the first surface, a frontside guard wiring structure disposed on the first surface of the guard structure, and a backside guard wiring structure disposed on the second surface of the guard structure.

The guard structure includes a connection via pattern connected to the backside guard wiring structure and extending in a first direction substantially perpendicular to a surface of the substrate by penetrating the substrate, and a first width of the connection via pattern at a first vertical level may be greater than a second width of the connection via pattern at a second vertical level more adjacent to the frontside guard wiring structure than the first vertical level.

According to some embodiments of the present disclosure, a semiconductor device includes a substrate including a central region and a peripheral region surrounding the central region, a guard structure disposed in the peripheral region and including a first surface and a second surface opposite to the first surface, a frontside guard wiring structure disposed on the first surface of the guard structure, and a backside guard wiring structure disposed on the second surface of the guard structure. The guard structure includes a connection via pattern connected to the backside guard wiring structure and the frontside guard wiring structure, the connection via pattern is a closed-type structure arranged in a zigzag shape having a plurality of bent portions along the peripheral region from a planar point of view, and a first width of the connection via pattern at a first vertical level may be greater than a second width of the connection via pattern at a second vertical level more adjacent to the frontside guard wiring structure than the first vertical level.

According to some embodiments of the present disclosure, a semiconductor device includes a substrate including a central region and a peripheral region surrounding the central region, a guard structure disposed in the peripheral region and including a first surface and a second surface opposite to the first surface, a frontside guard wiring structure disposed on the first surface of the guard structure, and a backside guard wiring structure disposed on the second surface of the guard structure. The frontside guard wiring structure includes a first frontside guard wiring pattern disposed on the first surface of the guard structure and extending in a first direction substantially parallel to the first surface, a second frontside guard wiring pattern spaced apart from the first frontside guard wiring pattern in a second direction crossing the first direction, and a frontside guard via pattern connecting the first frontside guard wiring pattern and the second frontside guard wiring pattern, the backside guard wiring structure includes a first backside guard wiring pattern disposed on the second surface of the guard structure and extending in the first direction, a second backside guard wiring pattern spaced apart from the first backside guard wiring pattern in the second direction, and a backside guard via pattern connecting the first backside guard wiring pattern and the second backside guard wiring pattern. The guard structure includes a connection via pattern connected to the backside guard wiring structure and the frontside guard wiring structure. A first width of the connection via pattern at a first vertical level is greater than a second width of the connection via pattern at a second vertical level more adjacent to the frontside guard wiring structure than the first vertical level, a first width of the frontside guard via pattern at a third vertical level is less than a second width of the frontside guard via pattern at a fourth vertical level farther from the guard structure than the third vertical level, and a first width of the backside guard via pattern at a fifth vertical level may be greater than a second width of the backside guard via pattern at a sixth vertical level more adjacent to the guard structure than the fifth vertical level.

According to some embodiments of the present disclosure, a method for manufacturing a semiconductor device includes providing a preliminary substrate including a central region and a peripheral region surrounding the central region, forming a guard interlayer insulating film in the peripheral region of the preliminary substrate, forming a frontside guard wiring structure on the guard interlayer insulating film, forming a guard structure by removing the preliminary substrate and forming a substrate including an insulating material, forming a connection via pattern by penetrating a backside of the guard structure, and forming a backside guard wiring structure on the backside of the guard structure. A first width of the connection via pattern at a first vertical level may be greater than a second width of the connection via pattern at a second vertical level more adjacent to the frontside guard wiring structure than the first vertical level.

According to some embodiments of the present disclosure, the method for manufacturing a semiconductor device further includes, before forming the frontside guard wiring structure, forming an upper contact by penetrating a frontside of the guard interlayer insulating film, wherein the upper contact is directly connected to the frontside guard wiring structure and the connection via pattern, and a first width of the upper contact at a third vertical level may be less than a second width of the upper contact at a fourth vertical level more adjacent to the frontside guard wiring structure than the third vertical level.

According to some embodiments of the present disclosure, the method for manufacturing a semiconductor device further includes, before forming the frontside guard wiring structure, forming a plurality of semiconductor layers, a guard gate electrode, a guard gate insulating film, a guard gate capping film, a guard gate spacer, a guard gate etch stop film, and a guard interlayer insulating film in the peripheral region of the preliminary substrate, and forming an upper contact by penetrating a frontside of the guard gate capping film, wherein a first width of the upper contact at a third vertical level may be less than a second width of the upper contact at a fourth vertical level more adjacent to the frontside guard wiring structure than the third vertical level.

According to some embodiments of the present disclosure, the method for manufacturing a semiconductor device further includes, before forming the frontside guard wiring structure, forming a guard source/drain pattern, a guard gate etch stop film, and a guard interlayer insulating film in the peripheral region of the preliminary substrate, and forming an upper contact by penetrating a frontside of the guard interlayer insulating film, wherein a first width of the upper contact at a third vertical level may be less than a second width of the upper contact at a fourth vertical level more adjacent to the frontside guard wiring structure than the third vertical level.

According to some embodiments of the present disclosure, the forming of the frontside guard wiring structure includes forming a first frontside guard wiring pattern on the guard interlayer insulating film, forming a frontside guard via pattern connected to the first frontside guard wiring pattern on the first frontside guard wiring pattern, and forming a second frontside guard wiring pattern connected to the frontside guard via pattern on the frontside guard via pattern, wherein a first width of the frontside guard via pattern at a third vertical level may be less than a second width of the frontside guard via pattern at a fourth vertical level farther from the guard structure than the third vertical level.

According to some embodiments of the present disclosure, the forming of the backside guard wiring structure includes forming a first backside guard wiring pattern on a backside of the substrate, forming a backside guard via pattern connected to the first backside guard wiring pattern on the first backside wiring pattern, and forming a second backside guard wiring pattern connected to the backside guard via pattern on the backside guard via pattern, wherein a first width of the backside guard via pattern at a third vertical level may be greater than a second width of the backside guard via pattern at a fourth vertical level more adjacent to the guard structure than the third vertical level.

According to exemplary embodiments of the present disclosure, a semiconductor device with improved reliability and/or electrical performance may be provided by protecting the operating characteristics of the semiconductor device and blocking external harmful environments.

The effects obtainable through the present disclosure are not limited to those mentioned above. Unmentioned technical effects will be clearly understood by those of ordinary skill in the art from the description of the invention described below.

### BRIEF DESCRIPTION OF THE DRAWINGS

FIG. 1 is an exemplary plan view for describing a semiconductor device according to some embodiments of the present disclosure.

FIG. 2 is an enlarged view of a region R1 of FIG. 1.

FIG. 3 is a cross-sectional view taken along line A-A of FIG. 2.

FIG. 4 is a cross-sectional view taken along line B-B of FIG. 2.

FIG. 5 is a cross-sectional view taken along line C-C of FIG. 2.

FIG. 6 is an enlarged view of a region R2 of FIG. 1.

FIG. 7 is a cross-sectional view taken along line D-D of FIG. 6.

FIG. 8 is an enlarged view of a region R2 of FIG. 1.

FIG. 9 is a cross-sectional view taken along line E-E of FIG. 8.

FIG. 10 is an enlarged view of a region R2 of FIG. 1.

FIG. 11 is a cross-sectional view taken along line F-F of FIG. 10.

FIG. 12 is a cross-sectional view taken along line G-G of FIG. 10.

FIG. 13 is an enlarged view of a region R2 of FIG. 1.

FIG. 14 is an enlarged view of FIG. 13.

FIG. 15 is an enlarged view of a region R2 of FIG. 1.

FIG. 16 is an enlarged view of FIG. 15.

FIGS. 17 to 20 are diagrams for explaining a method of manufacturing a circuit structure according to some embodiments.

FIGS. 21 to 24 are diagrams for explaining a method of manufacturing a guard structure according to some embodiments.

FIGS. 25 to 28 are diagrams for explaining a method of manufacturing a guard structure according to some embodiments.

FIGS. 29 to 32 are diagrams for explaining a method of manufacturing a guard structure according to some embodiments.

FIGS. 33 to 36 are diagrams for explaining a method of manufacturing a guard structure according to some embodiments.

### DETAILED DESCRIPTION

Hereinafter, various embodiments of the present disclosure will be described with reference to the drawings. Throughout the specification, the same reference numerals may refer to the same constituent elements.

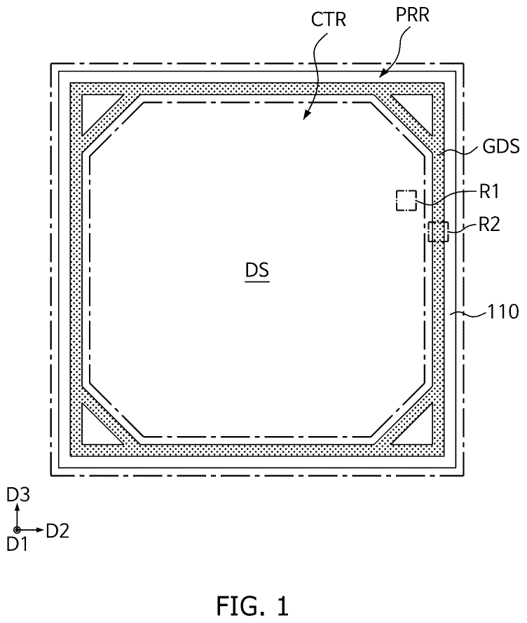

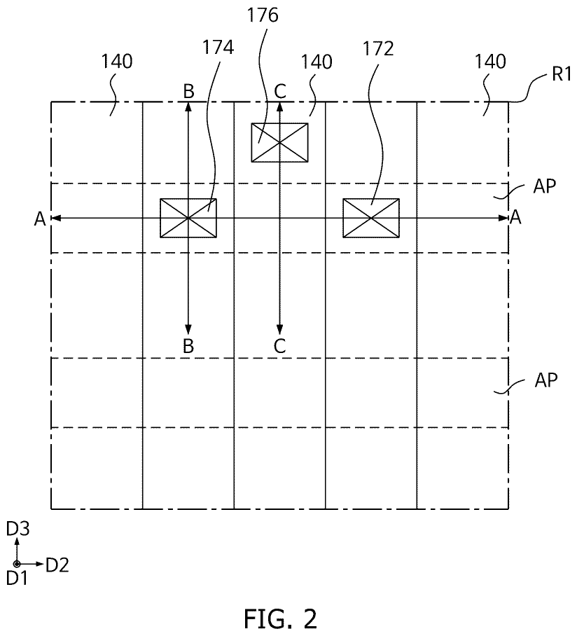

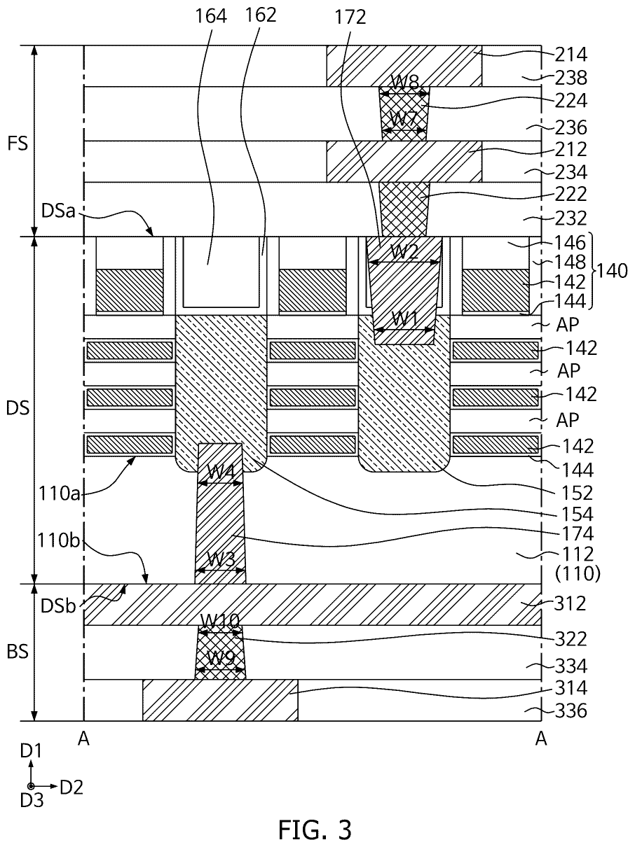

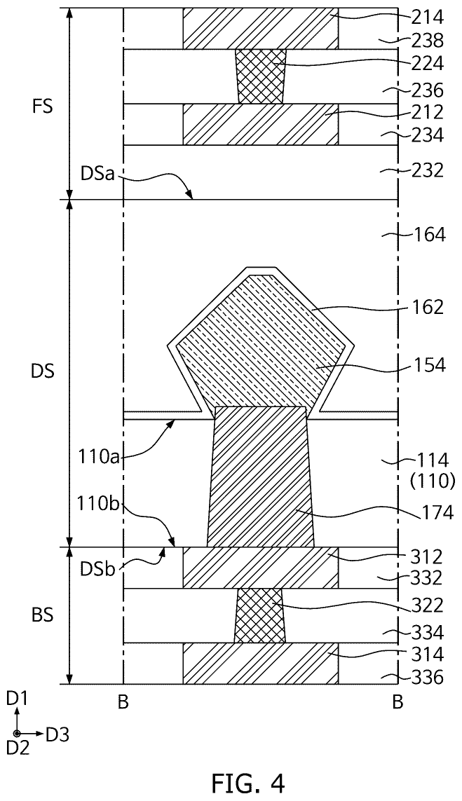

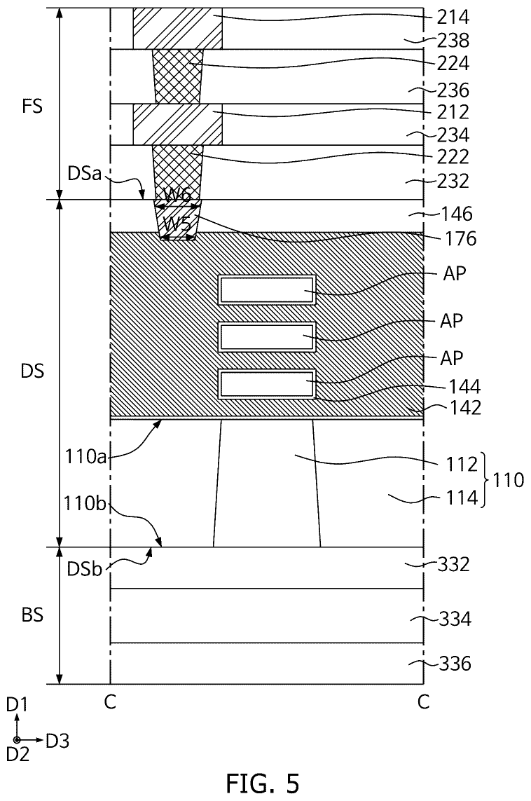

FIG. 1 is an exemplary plan view for describing a semiconductor device according to some embodiments of the present disclosure. FIG. 2 is an enlarged view of a region R1 of FIG. 1. FIG. 3 is a cross-sectional view taken along line A-A of FIG. 2. FIG. 4 is a cross-sectional view taken along line B-B of FIG. 2. FIG. 5 is a cross-sectional view taken along line C-C of FIG. 2.

Referring to FIGS. 1 to 5, a semiconductor device according to some embodiments of the present disclosure may include a substrate 110 including a central region CTR and a peripheral region PRR surrounding the central region CTR, a circuit structure DS including a structure disposed in the central region CTR, and a guard structure GDS disposed in the peripheral region PRR. In some embodiments, the guard structure GDS may be disposed to surround the central region CTR along the peripheral region PRR of the substrate 110. For example, the guard structure GDS may be a ring structure surrounding the central region CTR from a planar point of view.

The substrate 110 may include a first surface 110a and a second surface 110b opposite to the first surface 110a. In the present specification, the first surface 110a of a specific component may also be referred to as a frontside, and the second surface 110b of a specific component may also be referred to as a backside.

In some embodiments, the substrate 110 may include an insulating material. For example, the substrate 110 may be an insulating substrate including at least one of silicon oxide, silicon oxynitride, silicon oxycarbonitride, or a combination thereof.

In some embodiments, the substrate 110 may include a plurality of base patterns 112 and a field insulating film 114.

The base patterns 112 may be spaced apart from one another and extend in a direction parallel to a surface (e.g., the first surface 110a) of the substrate 110. In the present specification, a first direction D1 may denote a direction perpendicular to the surface of the substrate 110. Also, a second direction D2 and a third direction D3 may denote directions parallel to the surface of the substrate 110, and the second direction D2 and the third direction D3 may intersect one another.

For example, the base patterns 112 may each extend in the second direction D2 and be spaced apart from one another in the third direction D3. In some embodiments, each of the base patterns 112 may include an insulating material. For example, each of the base patterns 112 may include at least one of silicon oxide, silicon nitride, silicon oxycarbide, silicon oxynitride, silicon oxycarbonitride, or a combination thereof, but is not limited thereto.

The field insulating film 114 may cover at least a portion of a side surface of each of the base patterns 112. For example, the field insulating film 114 may fill a space between the base patterns 112. The field insulating film 114 may include, for example, at least one of silicon oxide, silicon nitride, silicon oxycarbide, silicon oxynitride, silicon oxycarbonitride, and a combination thereof, but is not limited thereto.

The field insulating film 114 may include the same material as the base patterns 112, or may include a material different from that of the base patterns 112. In some embodiments, a lower surface of the field insulating film 114 may be disposed coplanar with a lower surface of the base patterns 112. In some embodiments, an upper surface of the field insulating film 114 may be disposed coplanar with an upper surface of the base patterns 112. Terms such as “planar”, “coplanar”, “parallel”, “perpendicular”, “same”, “equal”, etc. used in the present specification should be interpreted as including an error range (e.g., ±10%), including, for example, variations that may occur during a manufacturing process.

The circuit structure DS may be disposed in the central region CTR of the substrate 110 and may include a plurality of active patterns AP, a plurality of device gate structures 140, a plurality of source/drain patterns 152, 154, a device etch stop film 162, a device interlayer insulating film 164, an upper device contact 172, a lower device contact 174, and a device gate contact 176.

In the present specification, spatially relative terms such as “above”, “upper”, “upper surface”, “below”, “lower”, “lower surface”, “side surface”, etc. are used to describe a direction shown in the drawings based on the reference numerals in the drawings, unless otherwise stated. Such spatially relative terms should be interpreted as including not only the direction shown in the drawings, but also various directions or arrangement states in which a device is actually used or operated.

A plurality of the active patterns AP may be disposed on the first surface 110a of the substrate 110. For example, the active patterns AP may extend side by side while being spaced apart from one another. For example, the active patterns AP may each extend in the second direction D2 and may be spaced apart from one another in the third direction D3.

Each of the active patterns AP may include an elemental semiconductor material, silicon (Si) or germanium (Ge). For example, each of the active patterns AP may include a silicon pattern. Alternatively, each of the active patterns AP may include a compound semiconductor, for example, a group IV-IV compound semiconductor or a group III-V compound semiconductor. The group IV-IV compound semiconductor may be, for example, a binary compound, a ternary compound including at least two or more of carbon (C), silicon (Si), germanium (Ge), and tin (Sn), or a compound doped with a group IV element. The group III-V compound semiconductor may be, for example, one of a binary compound, a ternary compound, or a quaternary compound formed by combining at least one of group III elements such as aluminum (Al), gallium (Ga), and indium (In) and at least one of group V elements such as phosphorus (P), arsenic (As), and antimony (Sb).

In some embodiments, the active patterns AP may be disposed on an upper surface of the base patterns 112 extending in the second direction D2. For example, the active patterns AP and the base patterns 112 may overlap in the first direction D1. A component or layer described as being “overlapped” with respect to a specific direction may mean that the component or layer may at least partially cover one another when viewed along a line extending in that direction or when viewed in a plane perpendicular to that direction.

Each of the active patterns AP may protrude in the first direction D1 on the first surface 110a of the substrate 110. In some embodiments, each of the active patterns AP may include a plurality of nanosheet patterns stacked on the base pattern 112 while being spaced apart from one another. The number of the plurality of nanosheet patterns included in each of the active patterns AP is merely exemplary and is not limited to what is shown. Also, the active patterns AP may be implemented as a plurality of nanowire patterns disposed on the substrate 110 while being spaced apart from one another. Alternatively, the active patterns AP may be implemented as a fin shape pattern protruding toward the first surface 110a of the substrate 110.

A plurality of the device gate structures 140 may be disposed on the substrate 110 and the active patterns AP. The device gate structures 140 may extend side by side while being spaced apart from one another in the second direction D2. Also, the device gate structures 140 may intersect the active patterns AP. For example, the device gate structures 140 may each extend in the third direction D3 and may be spaced apart from one another in the second direction D2.

Each of the device gate structures 140 may include a device gate electrode 142, a device gate insulating film 144, a device gate capping film 146, and a device gate spacer 148.

The device gate electrode 142 may be disposed on the active patterns AP. The device gate electrode 142 may surround a perimeter of each of the nanosheet patterns included in each of the active patterns AP. For example, the device gate electrode 142 may surround an upper surface, a lower surface, and both side surfaces in the third direction D3 of each of the nanosheet patterns. Each of the active patterns AP may extend in the second direction D2 to penetrate the device gate electrode 142.

The device gate insulating film 144 may be interposed between the nanosheet patterns included in each of the active patterns AP and the device gate electrode 142. For example, the device gate insulating film 144 may surround the perimeter of each of the nanosheet patterns.

The device gate insulating film 144 may include, for example, at least one of silicon oxide, silicon oxynitride, silicon nitride, or a high-k material having a dielectric constant greater than that of silicon oxide. The high-k material may include, for example, at least one of hafnium oxide (HfO2), zirconium oxide (ZrO2), lanthanum oxide (La2O3), aluminum oxide (A12O3), titanium oxide (TiO2), strontium titanium oxide (SrTiO3), lanthanum aluminum oxide (LaAlO3), yttrium oxide (Y2O3), hafnium oxynitride (HfOxNy), zirconium oxynitride (ZrOxNy), lanthanum oxynitride (La2OxNy), aluminum oxynitride (Al2OxNy), titanium oxynitride (TiOxNy), strontium titanium oxynitride (SrTiOxNy), lanthanum aluminum oxynitride (LaAlOxNy), yttrium oxynitride (Y2OxNy), and a combination thereof. However, the high-k material is not limited thereto.

Although the device gate electrode 142 is shown as a single film, this is only an example, and it is a matter of course that the device gate electrode 142 may be formed by stacking a plurality of conductive layers. For example, the device gate electrode 142 may include a work function adjustment film that adjusts a work function, and a filling conductive film that fills a space formed by the work function adjustment film. The work function adjustment film may include, for example, at least one of TiN, TaN, TiC, TaC, TiAlC, and a combination thereof. The filling conductive film may include, for example, W or Al.

The device gate spacer 148 may be disposed on side surfaces of the device gate electrode 142 that face one another in the second direction D2. The side surfaces of the device gate electrode 142 may include a portion where the device gate spacer 148 is disposed. For example, the device gate spacer 148 may be disposed on side surfaces of an upper device gate electrode facing one another, the upper device gate electrode disposed on top of an uppermost nanosheet among the plurality of nanosheets, and the device gate spacer 148 may extend in the third direction D3 along the device gate electrode 142.

The device gate spacer 148 may include an insulating material, for example, at least one of silicon nitride, silicon oxynitride, silicon oxycarbide, silicon boron nitride, silicon boron carbonitride, silicon oxycarbonitride, and a combination thereof, but is not limited thereto. For example, the device gate spacer 148 may include a silicon nitride film.

The device gate capping film 146 may be disposed on an upper surface of the device gate electrode 142. The device gate capping film 146 may extend along the upper surface of the device gate electrode 142. Although an upper surface of the device gate capping film 146 is shown only as being disposed coplanar with an upper surface of the device gate spacer 148, this is only an example. As another example, the device gate capping film 146 may cover the upper surface of the device gate spacer 148.

The device gate capping film 146 may include an insulating material, for example, at least one of silicon nitride, silicon oxynitride, silicon oxycarbide, silicon boron nitride, silicon boron carbonitride, silicon oxycarbonitride, and a combination thereof, but is not limited thereto. For example, the device gate capping film 146 may include a silicon nitride film.

The source/drain patterns 152, 154 may be disposed on side surfaces of the active patterns AP. For example, side surfaces of the plurality of nanosheets included in the active patterns AP that face one another in the second direction D2 may include portions connected to the source/drain patterns 152, 154. Also, side surfaces of the device gate structures 140 that face one another in the second direction D2 may include portions connected to the source/drain patterns 152, 154.

In the present specification, when a component is referred to as being “connected” to another component, this may mean that the component may be directly connected or coupled to the other component, or one or more intervening elements may be present therebetween. On the other hand, when a component is referred to as being “directly connected” or “contacting”, this may mean that no intervening element is present at that point of contact.

In some embodiments, each of the source/drain patterns 152, 154 may include an epitaxial layer. For example, the source/drain patterns 152, 154 may be formed by an epitaxial growth process using the active patterns AP and/or a silicon substrate (e.g., 700) as a seed layer.

When a field effect transistor of the circuit structure DS is an NFET, the source/drain patterns 152, 154 may include an n-type impurity or an impurity for preventing diffusion of the n-type impurity. For example, the source/drain patterns 152, 154 may include at least one of P, Sb, As, and a combination thereof.

When a field effect transistor of the circuit structure DS is a PFET, the source/drain patterns 152, 154 may include a p-type impurity or an impurity for preventing diffusion of the p-type impurity. For example, the source/drain patterns 152, 154 may include at least one of B, C, In, Ga, Al, and a combination thereof.

The device etch stop film 162 may be disposed along a profile of an upper surface of the field insulating film 114 and each of the source/drain patterns 152, 154 in the third direction D3. Also, the device etch stop film 162 may include a U-shaped film disposed on top of each of the source/drain patterns 152, 154 and on the side surface of the device gate spacer 148 in a cross-sectional structure along the second direction D2.

The device etch stop film 162 may include an insulating material, for example, at least one of silicon nitride, silicon oxynitride, silicon oxycarbide, silicon boron nitride, silicon boron carbonitride, silicon oxycarbonitride, and a combination thereof, but is not limited thereto. For example, the device etch stop film 162 may include a silicon nitride film.

The device interlayer insulating film 164 may cover the upper surface of the field insulating film 114 and each of the source/drain patterns 152, 154. Also, the device interlayer insulating film 164 may fill a space between side surfaces of the device gate spacer 148 that face one another in the second direction D2. The device etch stop film 162 may be interposed between the device interlayer insulating film 164 and the field insulating film 114, between the device interlayer insulating film 164 and each of the source/drain patterns 152, 154, and between the device interlayer insulating film 164 and the device gate spacer 148.

The device interlayer insulating film 164 may each include, for example, at least one of silicon oxide, silicon nitride, silicon oxynitride, silicon oxycarbide, silicon boron nitride, silicon boron carbonitride, silicon oxycarbonitride, and a low-k material having a dielectric constant lower than that of silicon oxide. The low-k material may include, for example, at least one of Flowable Oxide (FOX), Torene SilaZene (TOSZ), Undoped Silica Glass (USG), Borosilica Glass (BSG), PhosphoSilicaGlass (PSG), BoroPhosphoSilica Glass (BPSG), Plasma Enhanced Tetra Ethyl Ortho Silicate (PETEOS), Fluoride Silicate Glass (FSG), Carbon Doped silicon Oxide (CDO), Xerogel, Aerogel, Amorphous Fluorinated Carbon, Organo Silicate Glass (OSG), Parylene, bis-benzocyclobutenes (BCB), SiLK, polyimide, porous polymeric material, and a combination thereof, but is not limited thereto.

The upper device contact 172 may be disposed on a first source/drain pattern 152. For example, the upper device contact 172 may extend in the first direction D1, penetrate the device interlayer insulating film 164, and be directly connected to an upper surface of the first source/drain pattern 152.

In some embodiments, a width of the upper device contact 172 may decrease toward the first source/drain pattern 152, for example, in a downward direction. For example, a first width W1 in the second direction D2 of the upper device contact 172 at a first vertical level may be less than a second width W2 in the second direction D2 of the upper device contact 172 at a second vertical level. Here, the second vertical level may be higher than the first vertical level. For example, the second vertical level may be adjacent to a frontside device wiring structure FS more than the first vertical level. A cross-sectional shape of the upper device contact 172 may be due to an etching process for forming the upper device contact 172 being performed from a first surface DSa of the circuit structure DS toward the upper surface of the first source/drain pattern 152.

The term “vertical level” as used in the present specification may mean a relative distance (e.g., a distance along the first direction D1) that a component or surface has with respect to a reference element or surface (e.g., a surface of a wiring pattern (e.g., 314) or an insulating pattern (e.g., 336) disposed at the lowermost part of a semiconductor device) located below or above the component or surface.

The lower device contact 174 may be disposed on a second source/drain pattern 154. For example, the lower device contact 174 may extend in the first direction D1, penetrate the substrate 110 (e.g., the base pattern 112), and be directly connected to a lower surface of the second source/drain pattern 154.

In some embodiments, a width of the lower device contact 174 may decrease toward the second source/drain pattern 154, for example, in an upward direction. For example, a third width W3 in the second direction D2 of the lower device contact 174 at a third vertical level may be greater than a fourth width W4 in the second direction D2 of the lower device contact 174 at a fourth vertical level. Here, the fourth vertical level may be higher than the third vertical level. For example, the fourth vertical level may be farther from a backside device wiring structure BS than the third vertical level. A cross-sectional shape of the lower device contact 174 may be due to an etching process for forming the lower device contact 174 being performed from a second surface 110b of the substrate 110 toward the lower surface of the second source/drain pattern 154.

The device gate contact 176 may be disposed on the device gate electrode 142. For example, the device gate contact 176 may extend in the first direction D1, penetrate the device gate capping film 146, and be directly connected to an upper surface of the device gate electrode 142.

In some embodiments, a width of the device gate contact 176 may decrease toward the device gate electrode 142, for example, in a downward direction. For example, a fifth width W5 in the third direction D3 of the device gate contact 176 at a fifth vertical level may be less than a sixth width W6 in the third direction D3 of the device gate contact 176 at a sixth vertical level. Here, the sixth vertical level may be higher than the fifth vertical level. For example, the sixth vertical level may be adjacent to the frontside device wiring structure FS more than the fifth vertical level. A cross-sectional shape of the device gate contact 176 may be due to an etching process for forming the device gate contact 176 being performed from the first surface DSa of the circuit structure DS toward the upper surface of the device gate electrode 142.

The upper device contact 172 and the lower device contact 174 may include a conductive metal, for example, at least one of cobalt (Co), titanium (Ti), tantalum (Ta), ruthenium (Ru), tungsten (W), cobalt tungsten phosphorus (CoWP), or a combination thereof, but are not limited thereto.

The upper device contact 172 may include a silicide film interposed at an interface with the first source/drain pattern 152. Also, the lower device contact 174 may include a silicide film interposed at an interface with the second source/drain pattern 154. The silicide film may include a metal silicide, for example, at least one of nickel silicide, cobalt silicide, tungsten silicide, titanium silicide, niobium silicide, tantalum silicide, or a combination thereof, but is not limited thereto. For example, the silicide film may include a titanium silicide film.

The circuit structure DS may include a first surface DSa and a second surface DSb opposite to the first surface DSa. The first surface DSa of the circuit structure DS may correspond to an upper surface of the device interlayer insulating film 164, and the second surface DSb of the circuit structure DS may correspond to the second surface 110b of the substrate 110.

The semiconductor device may further include the frontside device wiring structure FS disposed on the circuit structure DS. The frontside device wiring structure FS may be disposed on the first surface DSa of the circuit structure DS. For example, the frontside device wiring structure FS may be formed on the upper surface of the device interlayer insulating film 164.

The frontside device wiring structure FS may include a plurality of frontside device inter-wiring insulating films 232, 234, 236, 238, a plurality of frontside device wiring patterns 212, 214, and a plurality of frontside device via patterns 222, 224.

The frontside device wiring patterns 212, 214 may be sequentially stacked on the device interlayer insulating film 164. For example, a first frontside device wiring pattern 212 may be disposed spaced apart from the upper device contact 172 in the first direction D1. A second frontside device wiring pattern 214 may be disposed spaced apart from the first frontside device wiring pattern 212 in the first direction D1.

The frontside device via patterns 222, 224 may interconnect the frontside device wiring patterns 212, 214. For example, a first frontside device via pattern 222 may connect the upper device contact 172 and the first frontside device wiring pattern 212. A lower portion of the first frontside device via pattern 222 may be directly connected to an upper portion of the upper device contact 172, and an upper portion of the first frontside device via pattern 222 may be directly connected to a lower portion of the first frontside device wiring pattern 212. Also, a second frontside device via pattern 224 may connect the first frontside device wiring pattern 212 and the second frontside device wiring pattern 214. A lower portion of the second frontside device via pattern 224 may be directly connected to an upper portion of the first frontside device wiring pattern 212, and an upper portion of the second frontside device via pattern 224 may be directly connected to a lower portion of the second frontside device wiring pattern 214.

In some embodiments, a width of the frontside device via patterns 222, 224 may decrease in a downward direction. For example, a seventh width W7 in the second direction D2 of the second frontside device via pattern 224 at a seventh vertical level may be less than an eighth width W8 in the second direction D2 of the second frontside device via pattern 224 at an eighth vertical level. Here, the eighth vertical level may be higher than the seventh vertical level. For example, the eighth vertical level may be farther from the circuit structure DS than the seventh vertical level. A cross-sectional shape of the second frontside device via pattern 224 may be due to an etching process for forming the second frontside device via pattern 224 being performed toward an upper surface of the first frontside device wiring pattern 212.

The frontside device wiring patterns 212, 214 and the frontside device via patterns 222, 224 may be formed within the frontside device inter-wiring insulating films 232, 234, 236, 238. The number of layers, number, and arrangement of the frontside device inter-wiring insulating films 232, 234, 236, 238, the frontside device wiring patterns 212, 214, and the frontside device via patterns 222, 224 are only exemplary and are not limited to what is shown.

The semiconductor device may further include the backside device wiring structure BS disposed on the circuit structure DS. The backside device wiring structure BS may be disposed on the second surface DSb of the circuit structure DS (e.g., the second surface 110b of the substrate 110).

The backside device wiring structure BS may include a plurality of backside device inter-wiring insulating films 332, 334, 336, a plurality of backside device wiring patterns 312, 314, and a backside device via pattern 322.

The backside device wiring patterns 312, 314 may be sequentially stacked on the second surface 110b of the substrate 110. For example, a first backside device wiring pattern 312 may be disposed on a lower surface of the lower device contact 174. A second backside device wiring pattern 314 may be disposed spaced apart from the first backside device wiring pattern 312 in the first direction D1.

The backside device via pattern 322 may interconnect the backside device wiring patterns 312, 314. For example, the backside device via pattern 322 may connect the first backside device wiring pattern 312 and the second backside device wiring pattern 314. A lower portion of the backside device via pattern 322 may be directly connected to an upper portion of the second backside device wiring pattern 314, and an upper portion of the backside device via pattern 322 may be directly connected to a lower portion of the first backside device wiring pattern 312.

In some embodiments, a width of the backside device via pattern 322 may decrease in an upward direction. For example, a ninth width W9 in the second direction D2 of the backside device via pattern 322 at a ninth vertical level may be greater than a tenth width W10 in the second direction D2 of the backside device via pattern 322 at a tenth vertical level. Here, the tenth vertical level may be higher than the ninth vertical level. For example, the tenth vertical level may be adjacent to the circuit structure DS more than the ninth vertical level. A cross-sectional shape of the backside device via pattern 322 may be due to an etching process for forming the backside device via pattern 322 being performed toward a lower surface of the first backside device wiring pattern 312.

The backside device wiring patterns 312, 314 and the backside device via pattern 322 may be formed within the backside device inter-wiring insulating films 332, 334, 336. The number of layers, number, and arrangement of the backside device inter-wiring insulating films 332, 334, 336, the backside device wiring patterns 312, 314, and the backside device via pattern 322 are only exemplary and are not limited to what is shown.

Although not specifically shown, the frontside device wiring patterns 212, 214 and the frontside device via patterns 222, 224, and the backside device wiring patterns 312, 314 and the backside device via pattern 322 may each include a barrier conductive film and a filling conductive film. The barrier conductive film may include a metal or a metal nitride for preventing diffusion of the filling conductive film. The barrier conductive film may include, for example, at least one of titanium (Ti), tantalum (Ta), tungsten (W), nickel (Ni), cobalt (Co), platinum (Pt), an alloy thereof, and a nitride thereof, but is not limited thereto. The filling conductive film may include, for example, at least one of aluminum (Al), copper (Cu), tungsten (W), molybdenum (Mo), cobalt (Co), ruthenium (Ru), and an alloy thereof, but is not limited thereto.

In some embodiments, the backside device wiring structure BS may include a power supply line. For example, the first backside device wiring pattern 312 may be a power supply line. The first backside device wiring pattern 312 may extend along the second surface 110b of the substrate 110. Also, the first backside device wiring pattern 312, which is a power supply line, may be connected to the lower device contact 174. However, the scope of the present disclosure is not limited thereto.

A semiconductor device according to some embodiments may include a Back Side Power Delivery Network (BSPDN). For example, the backside device wiring structure BS disposed on the second surface DSb of the circuit structure DS may provide a power delivery network (PDN). Such a configuration may contribute to reducing the wiring density of a frontside wiring layer (for example, the frontside device wiring structure FS), and may further minimize the resistance and inductance of a power path. Accordingly, the semiconductor device according to the present embodiment may have improved power delivery efficiency, reduce a voltage drop, and also contribute to reducing a total area of the device.

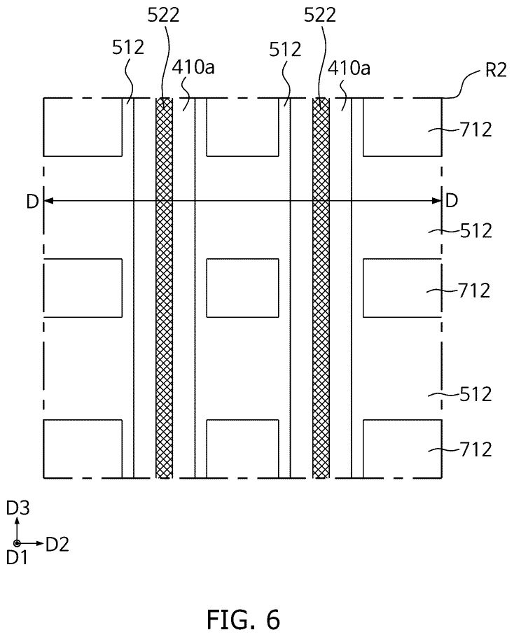

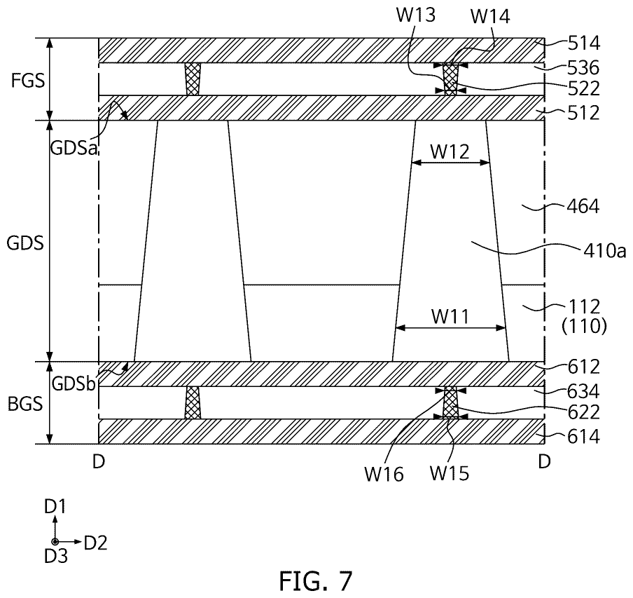

FIGS. 6 and 7 are exemplary drawings for describing a guard structure according to some embodiments. FIG. 6 is an enlarged view of a region R2 of FIG. 1. FIG. 7 is a cross-sectional view taken along line D-D of FIG. 6.

Referring to FIGS. 6 and 7, the guard structure GDS may be disposed in the peripheral region PRR of the substrate 110. The guard structure GDS may be disposed to surround the central region CTR along the peripheral region PRR.

The guard structure GDS may be disposed in the peripheral region PRR of the substrate 110 and may include a guard interlayer insulating film 464 and a connection via pattern 410a.

The guard structure GDS may include a first surface GDSa and a second surface GDSb opposite to the first surface GDSa. The semiconductor device may further include a frontside guard wiring structure FGS disposed on the first surface GDSa of the guard structure GDS and a backside guard wiring structure BGS disposed on the second surface GDSb of the guard structure GDS. The first surface GDSa of the guard structure GDS may be disposed coplanar with the first surface DSa of the circuit structure DS. Also, the second surface GDSb of the guard structure GDS may be disposed coplanar with the second surface DSb of the circuit structure DS. In some embodiments, a length of the guard structure GDS in the first direction D1 may have a unit of several tens of nm to several hundreds of nm. However, the scope of the present disclosure is not limited thereto.

The guard interlayer insulating film 464 may cover an upper surface of the peripheral region PRR of the substrate 110. The guard interlayer insulating film 464 may each include, for example, at least one of silicon oxide, silicon nitride, silicon oxynitride, silicon oxycarbide, silicon boron nitride, silicon boron carbonitride, silicon oxycarbonitride, and a low-k material having a dielectric constant lower than that of silicon oxide. The low-k material may include, for example, at least one of Flowable Oxide (FOX), Torene SilaZene (TOSZ), Undoped Silica Glass (USG), Borosilica Glass (BSG), PhosphoSilicaGlass (PSG), BoroPhosphoSilica Glass (BPSG), Plasma Enhanced Tetra Ethyl Ortho Silicate (PETEOS), Fluoride Silicate Glass (FSG), Carbon Doped silicon Oxide (CDO), Xerogel, Aerogel, Amorphous Fluorinated Carbon, Organo Silicate Glass (OSG), Parylene, bis-benzocyclobutenes (BCB), SiLK, polyimide, porous polymeric material, and a combination thereof, but is not limited thereto.

The connection via pattern 410a may penetrate the substrate 110 (e.g., the base pattern 112) and the guard interlayer insulating film 464 in the peripheral region PRR and extend in the first direction D1. The connection via pattern 410a may be connected to the backside guard wiring structure BGS and the frontside guard wiring structure FGS.

In some embodiments, the connection via pattern 410a may be directly connected to the backside guard wiring structure BGS and the frontside guard wiring structure FGS. A lower portion of the connection via pattern 410a may be directly connected to the backside guard wiring structure BGS, and an upper portion of the connection via pattern 410a may be directly connected to the frontside guard wiring structure FGS.

In some embodiments, the connection via pattern 410a may be disposed to surround the central region CTR along the peripheral region PRR. For example, the connection via pattern 410a may be a ring structure surrounding the central region CTR.

In some embodiments, a width of the connection via pattern 410a may decrease in an upward direction. For example, an eleventh width W11 in the second direction D2 of the connection via pattern 410a at an eleventh vertical level may be greater than a twelfth width W12 in the second direction D2 of the connection via pattern 410a at a twelfth vertical level. Here, the twelfth vertical level may be higher than the eleventh vertical level. For example, the twelfth vertical level may be adjacent to the frontside guard wiring structure FGS more than the eleventh vertical level. A cross-sectional shape of the connection via pattern 410a may be due to an etching process for forming the connection via pattern 410a being performed from the second surface GDSb of the guard structure GDS in a direction of the first surface GDSa. The connection via pattern 410a may each include a barrier conductive film and a filling conductive film. The barrier conductive film may include a metal or a metal nitride for preventing diffusion of the filling conductive film. The barrier conductive film may include, for example, at least one of titanium (Ti), tantalum (Ta), tungsten (W), nickel (Ni), cobalt (Co), platinum (Pt), an alloy thereof, and a nitride thereof, but is not limited thereto. The filling conductive film may include, for example, at least one of aluminum (Al), copper (Cu), tungsten (W), molybdenum (Mo), cobalt (Co), ruthenium (Ru), and an alloy thereof, but is not limited thereto.

The frontside guard wiring structure FGS may include a plurality of frontside guard inter-wiring insulating films (e.g., 536), a plurality of frontside guard wiring patterns 512, 514, and a plurality of frontside guard via patterns (e.g., 522).

The frontside guard wiring patterns 512, 514 may be sequentially stacked on the guard interlayer insulating film 464. For example, a first frontside guard wiring pattern 512 may be disposed on the connection via pattern 410a. A second frontside guard wiring pattern 514 may be disposed spaced apart from the first frontside guard wiring pattern 512 in the first direction D1.

In some embodiments, the frontside guard wiring patterns 512, 514 may be arranged in a lattice shape from a planar point of view. Each of the frontside guard wiring patterns 512, 514 stacked in the lattice-shaped structure may overlap in the first direction D1. For example, frontside guard wiring patterns extending in the second direction D2 parallel to the surface of the substrate 110 and disposed spaced apart from one another in the third direction D3, and frontside guard wiring patterns extending in the third direction D3 and disposed spaced apart from one another in the second direction D2 are arranged alternately, so that the frontside guard wiring patterns 512, 514 may form a lattice-shaped structure. An insulating pattern 712 may be formed in a square planar structure formed by the lattice-shaped arrangement of the frontside guard wiring patterns 512, 514.

A frontside guard via pattern 522 (e.g., a second frontside guard via pattern 522) may interconnect the frontside guard wiring patterns 512, 514. For example, the frontside guard via pattern 522 may connect the first frontside guard wiring pattern 512 and the second frontside guard wiring pattern 514. A lower portion of the frontside guard via pattern 522 may be directly connected to an upper portion of the first frontside guard wiring pattern 512, and an upper portion of the frontside guard via pattern 522 may be directly connected to a lower portion of the second frontside guard wiring pattern 514.

In some embodiments, the frontside guard via patterns (e.g., 522) may be disposed to surround the central region CTR along the peripheral region PRR. For example, the frontside guard via patterns 522 may be a ring structure surrounding the central region CTR.

In some embodiments, a width of the frontside guard via pattern 522 may decrease in a downward direction. For example, a thirteenth width W13 in the second direction D2 of the frontside guard via pattern 522 at a thirteenth vertical level may be less than a fourteenth width W14 in the second direction D2 of the frontside guard via pattern 522 at a fourteenth vertical level. Here, the fourteenth vertical level may be higher than the thirteenth vertical level. For example, the fourteenth vertical level may be farther from the guard structure GDS than the thirteenth vertical level. A cross-sectional shape of the frontside guard via pattern 522 may be due to an etching process for forming the frontside guard via pattern 522 being performed toward an upper surface of the first frontside guard wiring pattern 512.

The frontside guard via patterns 522 may be formed in a frontside guard inter-wiring insulating film 536. Also, the frontside guard wiring patterns 512, 514 may be formed in frontside guard inter-wiring insulating films formed adjacent to the frontside guard inter-wiring insulating film 536 in the first direction D1. The number of layers, number, and arrangement of the frontside guard inter-wiring insulating films (e.g., 536), the frontside guard wiring patterns 512, 514, and the frontside guard via patterns 522 are only exemplary and are not limited to what is shown.

The backside guard wiring structure BGS may include a plurality of backside guard inter-wiring insulating films (e.g., 634), a plurality of backside guard wiring patterns 612, 614, and a plurality of backside guard via patterns (e.g., 622).

The backside guard wiring patterns 612, 614 may be sequentially stacked on the second surface GDSb of the guard structure GDS. For example, a first backside guard wiring pattern 612 may be disposed on the connection via pattern 410a. A second backside guard wiring pattern 614 may be disposed spaced apart from the first backside guard wiring pattern 612 in the first direction D1.

In some embodiments, the backside guard wiring patterns 612, 614 may be arranged in a lattice shape from a planar point of view and may be arranged the same as or similar to the frontside guard wiring patterns 512, 514.

A backside guard via pattern 622 may interconnect the backside guard wiring patterns 612, 614. For example, the backside guard via pattern 622 may connect the first backside guard wiring pattern 612 and the second backside guard wiring pattern 614.

An upper portion of the backside guard via pattern 622 may be directly connected to a lower portion of the first backside guard wiring pattern 612, and a lower portion of the backside guard via pattern 622 may be directly connected to an upper portion of the second backside guard wiring pattern 614.

In some embodiments, from a planar point of view, the backside guard via patterns (e.g., 622) may be disposed to surround the central region CTR along the peripheral region PRR. For example, the backside guard via patterns 622 may be a ring structure surrounding the central region CTR.

In some embodiments, a width of the backside guard via pattern 622 may decrease in an upward direction. For example, a fifteenth width W15 in the second direction D2 of the backside guard via pattern 622 at a fifteenth vertical level may be greater than a sixteenth width W16 in the second direction D2 of the backside guard via pattern 622 at a sixteenth vertical level. Here, the sixteenth vertical level may be higher than the fifteenth vertical level. For example, the sixteenth vertical level may be adjacent to the guard structure GDS more than the fifteenth vertical level. A cross-sectional shape of the backside guard via pattern 622 may be due to an etching process for forming the backside guard via pattern 622 being performed toward a lower surface of the first backside guard wiring pattern 612.

The backside guard via patterns 622 may be formed in a backside guard inter-wiring insulating film 634. Also, the backside guard wiring patterns 612, 614 may be formed in respective backside guard inter-wiring insulating films formed adjacent to the backside guard inter-wiring insulating film 634 in the first direction D1. The number of layers, number, and arrangement of the backside guard inter-wiring insulating films (e.g., 634), the backside guard wiring patterns 612, 614, and the backside guard via patterns 622 are only exemplary and are not limited to what is shown.

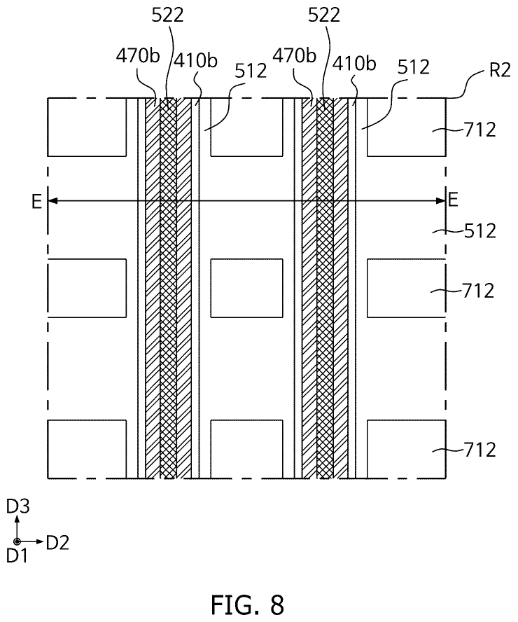

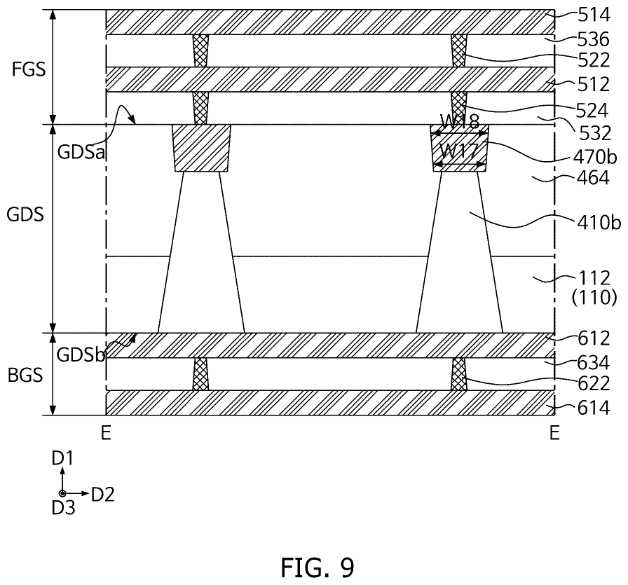

FIGS. 8 and 9 are exemplary drawings for describing a guard structure according to some embodiments. FIG. 8 is an enlarged view of a region R2 of FIG. 1.

FIG. 9 is a cross-sectional view taken along line E-E of FIG. 8. The guard structure GDS of FIGS. 8 and 9 may be substantially the same as the guard structure GDS described with reference to FIGS. 6 to 7, except that the guard structure GDS further includes an upper contact 470b. Also, a connection via pattern 410b of FIGS. 8 to 9 may be substantially the same as a connection via pattern 410a described with reference to FIGS. 6 to 7, except for a connection structure with the upper contact 470b. Hereinafter, for convenience of description, a configuration different from the configuration described in FIGS. 6 to 7 will be mainly described.

Referring to FIGS. 8 and 9, in some embodiments, the guard structure GDS may further include the upper contact 470b directly connected to the frontside guard wiring structure FGS. In some embodiments, the frontside guard wiring structure FGS may further include a first frontside guard via pattern 524 directly connecting the upper contact 470b and the first frontside guard wiring pattern 512. For example, a lower portion of the upper contact 470b may be directly connected to an upper portion of the connection via pattern 410b, and an upper portion of the upper contact 470b may be directly connected to the first frontside guard via pattern 524.

In some embodiments, a width of the upper contact 470b may decrease in a downward direction. For example, a seventeenth width W17 in the second direction D2 of the upper contact 470b at a seventeenth vertical level may be less than an eighteenth width W18 in the second direction D2 of the upper contact 470b at an eighteenth vertical level. Here, the eighteenth vertical level may be higher than the seventeenth vertical level. For example, the eighteenth vertical level may be adjacent to the frontside guard wiring structure FGS more than the seventeenth vertical level. A cross-sectional shape of the upper contact 470b may be due to an etching process for forming the upper contact 470b being performed from a first surface GDSa of the guard structure GDS toward the connection via pattern 410b.

In some embodiments, from a planar point of view, the upper contact 470b may be disposed to surround the central region CTR along the peripheral region PRR. For example, the upper contact 470b may be a ring structure surrounding the central region CTR.

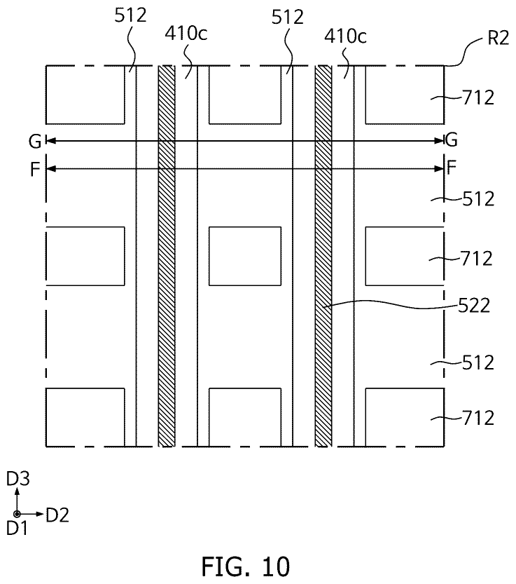

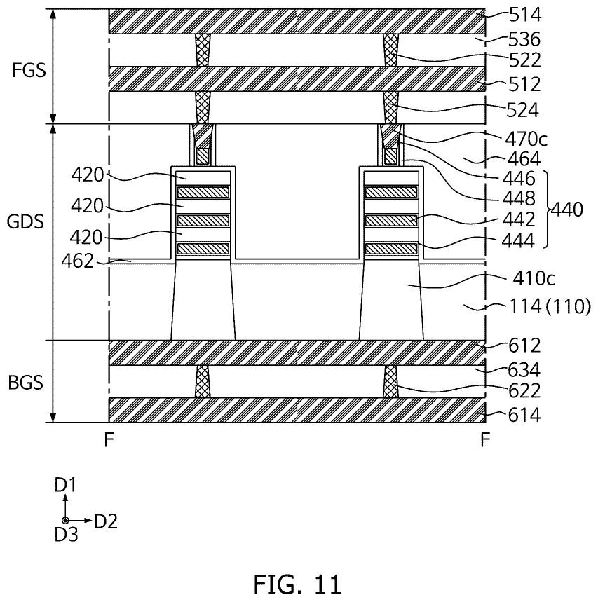

FIGS. 10 and 11 are exemplary drawings for describing a guard structure according to some embodiments. FIG. 10 is an enlarged view of a region R2 of FIG. 1. FIG. 11 is a cross-sectional view taken along line F-F of FIG. 10. The guard structure GDS of FIGS. 10 and 11 may be substantially the same as the guard structure GDS described with reference to FIGS. 8 and 9, except that the guard structure GDS includes a plurality of semiconductor layers 420 and a guard gate structure 440. Also, a connection via pattern 410c of FIGS. 10 and 11 may be substantially the same as the connection via pattern 410a described with reference to FIGS. 6 and 7 and the connection via pattern 410b described with reference to FIGS. 8 and 9, except for a connection structure with the plurality of semiconductor layers 420. Hereinafter, for convenience of description, a configuration different from the configuration described in FIGS. 6 to 9 will be mainly described.

Referring to FIGS. 10 and 11, in some embodiments, the guard structure GDS may further include a plurality of the semiconductor layers 420, the guard gate structure 440, and a guard gate etch stop film 462.

A plurality of the semiconductor layers 420 may be stacked on a surface of the substrate 110 while being spaced apart from one another in the first direction D1. The plurality of semiconductor layers 420 may include the same or a similar material as an active pattern of a circuit structure (e.g., DS of FIG. 2).

The guard gate structure 440 may include a guard gate electrode 442, a guard gate insulating film 444, a guard gate capping film 446, and a guard gate spacer 448.

The guard gate electrode 442 may surround each of the plurality of semiconductor layers 420. The guard gate electrode 442 may include the same or a similar material as a device gate electrode of a circuit structure (e.g., DS of FIG. 2).

The guard gate insulating film 444 may be interposed between each of the plurality of semiconductor layers 420 and the guard gate electrode 442. The guard gate insulating film 444 may include the same or a similar material as a device gate insulating film of a circuit structure (e.g., DS of FIG. 2).

The guard gate capping film 446 may be disposed on an upper surface of the guard gate electrode 442. The guard gate capping film 446 may include the same or a similar material as a device gate capping film of a circuit structure (e.g., DS of FIG. 2).

The guard gate spacer 448 may be disposed on both side surfaces facing in the second direction D2 of an upper guard gate electrode disposed on an uppermost semiconductor layer 420 of the plurality of semiconductor layers 420. The guard gate spacer 448 may include the same or a similar material as a device gate spacer of a circuit structure (e.g., DS of FIG. 2).

In some embodiments, the guard structure GDS may further include an upper contact 470c directly connected to the frontside guard wiring structure FGS. In some embodiments, the frontside guard wiring structure FGS may further include a first frontside guard via pattern 524 directly connecting the upper contact 470c and the first frontside guard wiring pattern 512. For example, a lower portion of the upper contact 470c may be directly connected to an upper portion of the guard gate electrode 442, and an upper portion of the upper contact 470c may be directly connected to the first frontside guard via pattern 524.

In some embodiments, the connection via pattern 410c may be directly connected to the backside guard wiring structure BGS and a lowermost semiconductor layer 420 of the plurality of semiconductor layers 420. For example, a lower portion of the connection via pattern 410c may be directly connected to the backside guard wiring structure BGS, and an upper portion of the connection via pattern 410c may be directly connected to the lowermost semiconductor layer 420.

In some embodiments, from a planar point of view, the plurality of semiconductor layers 420 may be disposed to surround the central region CTR along the peripheral region PRR. For example, the plurality of semiconductor layers 420 may be a ring structure surrounding the central region CTR.

In some embodiments, from a planar point of view, the guard gate electrode 442 may be disposed to surround the central region CTR along the peripheral region PRR. For example, the guard gate electrode 442 may be a ring structure surrounding the central region CTR.

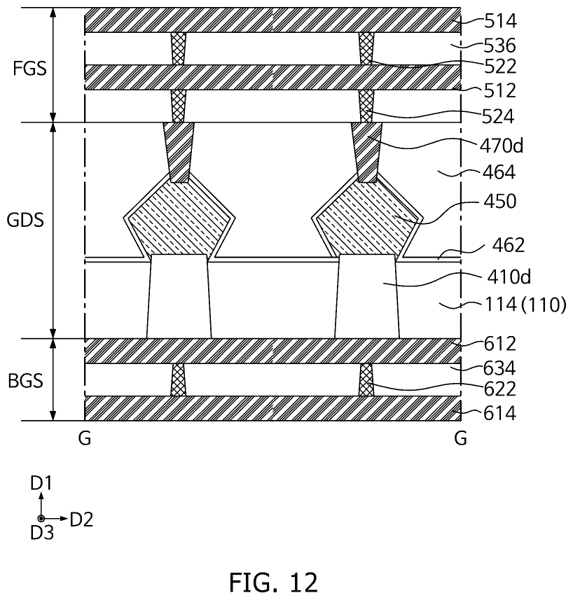

FIG. 12 is an exemplary drawing for describing a guard structure according to some embodiments. FIG. 12 is a cross-sectional view taken along line G-G of FIG. 10. The guard structure GDS of FIG. 12 may be substantially the same as the guard structure GDS described with reference to FIG. 11, except that the guard structure GDS further includes a guard source/drain pattern 450 and is configured to be alternately disposed with the guard structure GDS of FIG. 11 along the peripheral region PRR in the plan view of FIG. 10. Also, a connection via pattern 410d of FIG. 12 may be substantially the same as a connection via pattern 410c described with reference to FIG. 11, except for a connection structure further connected to the guard source/drain pattern 450. Hereinafter, for convenience of description, a configuration different from the configuration described in FIGS. 10 to 11 will be mainly described.

Referring to FIG. 12, in some embodiments, from a planar point of view, the plurality of semiconductor layers 420 and the guard source/drain pattern 450 may be alternately disposed along the peripheral region PRR to surround the central region CTR.

In some embodiments, a lower portion of an upper contact 470d may be directly connected to the guard source/drain pattern 450. In embodiments, the semiconductor layers 420 and the guard source/drain patterns 450 may be alternately disposed below the lower portion of the ring-structured upper contact 470d.

In some embodiments, an upper portion of the connection via pattern 410d may be directly connected to the semiconductor layers 420 and the guard source/drain pattern 450. For example, the semiconductor layers 420 and the guard source/drain patterns 450 may be alternately disposed on the upper portion of the ring-structured connection via pattern 410d.

As shown in FIGS. 6 to 12, the guard structures GDS of the peripheral region PRR represent an example in which structures of the same shape are disposed spaced apart in the second direction D2, but are not limited thereto. For example, the guard structures GDS of the peripheral region PRR may be disposed in a combination of structures of different shapes shown in FIGS. 6 to 12.

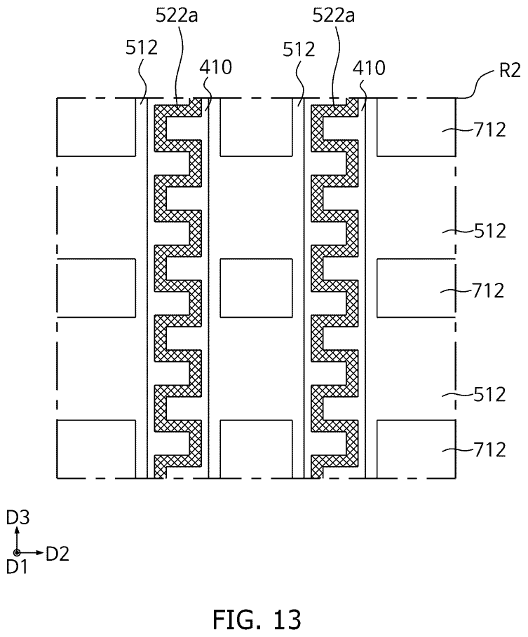

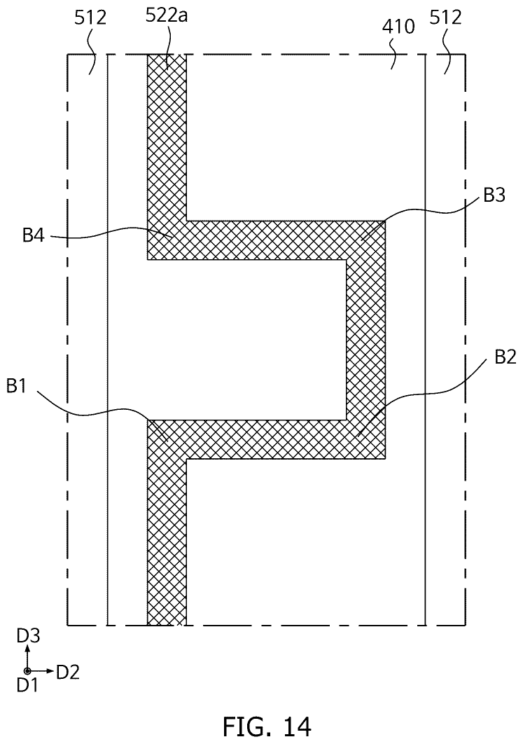

FIGS. 13 and 14 are exemplary plan views for describing a guard structure according to some embodiments. FIG. 13 is an enlarged view of a region R2 of FIG. 1. FIG. 14 is an enlarged view of FIG. 13. The guard structure GDS of FIGS. 13 and 14 may be substantially the same as the guard structure GDS described with reference to FIGS. 1 to 12, except that a frontside guard via pattern 522a has a different planar shape. Hereinafter, for convenience of description, a configuration different from the configuration described in FIGS. 1 to 12 will be mainly described.

Referring to FIGS. 13 and 14, in some embodiments, the frontside guard via pattern 522a may be arranged in a zigzag shape along the peripheral region PRR of the substrate 110. For example, the frontside guard via pattern 522a may be continuously arranged in a zigzag shape having a first bent section B1 bent from a third direction D3 to a second direction D2, a second bent section B2 bent from the second direction D2 to the third direction D3, a third bent section B3 bent from the third direction D3 to the second direction D2, and a fourth bent section B4 bent from the second direction D2 to the third direction D3 from a planar point of view.

Here, the first bent section B1 and the third bent section B3 form a symmetrical structure, and the second bent section B2 and the fourth bent section B4 may form a symmetrical structure. In FIGS. 13 and 14, the bent sections B1, B2, B3, B4 are shown as being bent at a right angle, but are not limited thereto. The bent sections B1, B2, B3, B4 may be bent at an angle other than a right angle, or may be bent in a curve.

Although FIGS. 13 and 14 show an example in which the frontside guard via pattern 522a has a zigzag shape, it is not limited thereto. Additionally or alternatively, the zigzag shape described with reference to FIGS. 13 and 14 may be equally applied to a backside guard via pattern 622, connection patterns 410a, 410b, 410c, upper contacts 470b, 470c, or a guard gate electrode 442.

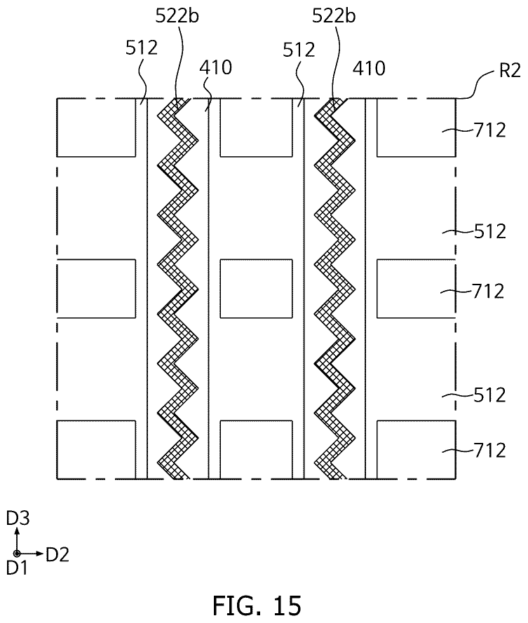

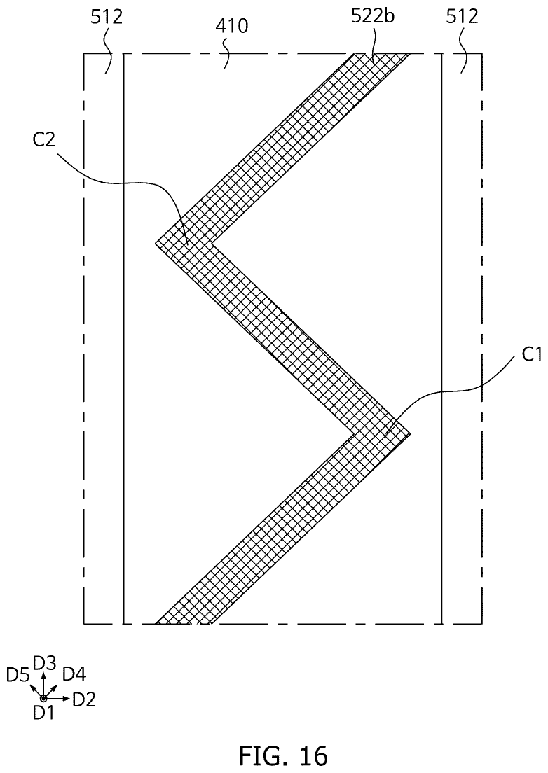

FIGS. 15 and 16 are exemplary plan views for describing a guard structure according to some embodiments. FIG. 15 is an enlarged view of a region R2 of FIG. 1. FIG. 16 is an enlarged view of FIG. 15. The guard structure GDS of FIGS. 15 and 16 may be substantially the same as the guard structure GDS described with reference to FIGS. 1 to 14, except that a frontside guard via pattern 522b has a different planar shape. Hereinafter, for convenience of description, a configuration different from the configuration described in FIGS. 1 to 14 will be mainly described.

Referring to FIGS. 15 and 16, in some embodiments, the frontside guard via pattern 522b may be arranged in a zigzag shape along the peripheral region PRR of the substrate 110. For example, the frontside guard via pattern 522b may be continuously arranged in a zigzag shape having a first bent section C1 bent from a fourth direction D4 to a fifth direction D5, and a second bent section C2 bent from the fifth direction D5 to the fourth direction D4 from a planar point of view. Here, the fourth direction D4 and the fifth direction D5 are directions parallel to a surface of the substrate 110, and second to fifth directions D2, D3, D4, D5 parallel to the surface of the substrate 110 may each intersect one another.

Here, the first bent section C1 and the second bent section C2 may form a symmetrical structure. In FIGS. 15 and 16, the bent sections C1, C2 are shown as being bent at a right angle, but are not limited thereto. The bent sections C1, C2 may be bent at an angle other than a right angle, or may be bent in a curve.

Although FIGS. 15 and 16 show an example in which the frontside guard via pattern 522b has a zigzag shape, it is not limited thereto. Additionally or alternatively, the zigzag shape described with reference to FIGS. 15 and 16 may be equally applied to a backside guard via pattern 622, connection patterns 410a, 410b, 410c, upper contacts 470b, 470c, or a guard gate electrode 442.

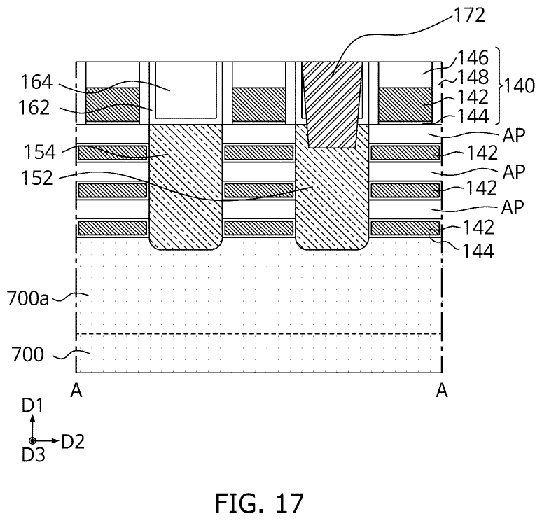

FIGS. 17 to 20 are diagrams for explaining a method of manufacturing a circuit structure according to some embodiments. FIGS. 17 to 20 are diagrams corresponding to a cross-sectional view taken along line A-A of FIG. 2.

Referring to FIG. 17, a preliminary substrate 700 including a central region (e.g., a region corresponding to the central region of the substrate 110) and a peripheral region surrounding the central region (e.g., a region corresponding to the peripheral region of the substrate 110) may be provided. The active pattern AP, the device gate structure 140, the device source/drain patterns 152, 154, the device etch stop film 162, the device interlayer insulating film 164, and the upper device contact 172 may be formed in the central region of the preliminary substrate 700. The device gate structure 140 may include the device gate electrode 142, the device gate insulating film 144, the device gate capping film 146, and the device gate spacer 148.

Here, the preliminary substrate 700 may be a silicon substrate, or may include another material, for example, silicon germanium (SiGe), silicon germanium on insulator (SGOI), indium antimonide, lead telluride compound, indium arsenide, indium phosphide, gallium arsenide, or gallium antimonide, but is not limited thereto.

In some embodiments, the preliminary substrate 700 may include a lower pattern 700a. The lower pattern 700a may extend in the second direction D2 on the preliminary substrate 700 and may include a portion protruding in a fin shape.

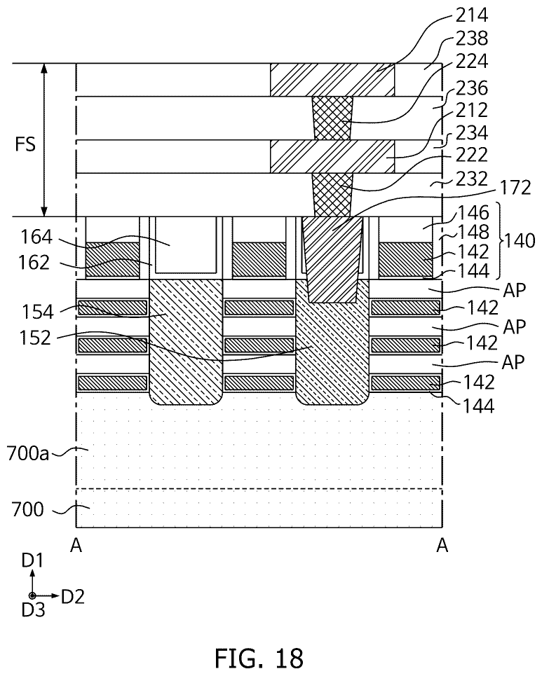

Referring to FIG. 18, the frontside device wiring structure FS may be formed on the device interlayer insulating film 164.

For example, a first frontside device inter-wiring insulating film 232 may be formed on the device interlayer insulating film 164, and the first frontside device via pattern 222 may be formed in the first frontside device inter-wiring insulating film 232.

A second frontside device inter-wiring insulating film 234 may be formed on the first frontside device inter-wiring insulating film 232, and the first frontside device wiring pattern 212 connected to the first frontside device via pattern 222 may be formed in the second frontside device inter-wiring insulating film 234.

A third frontside device inter-wiring insulating film 236 may be formed on the second frontside device inter-wiring insulating film 234, and the second frontside device via pattern 224 connected to the first frontside device wiring pattern 212 may be formed in the third frontside device inter-wiring insulating film 236.

A fourth frontside device inter-wiring insulating film 238 may be formed on the third frontside device inter-wiring insulating film 236, and the second frontside device wiring pattern 214 connected to the second frontside device via pattern 224 may be formed in the fourth frontside device inter-wiring insulating film 238.

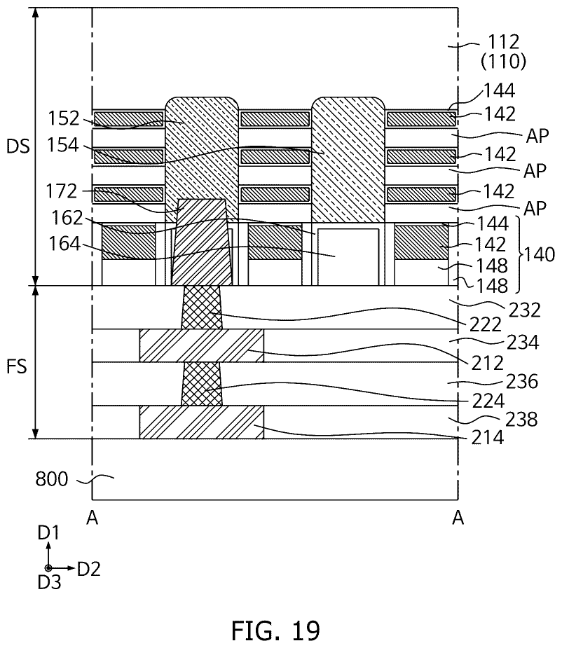

Referring to FIG. 19, the frontside device wiring structure FS may be attached on a carrier substrate 800. For example, a worksheet on which the manufacturing method of FIG. 18 has been performed may be inverted and attached so that a frontside of the frontside device wiring structure FS and a frontside of the carrier substrate 800 face one another. In some embodiments, the frontside device wiring structure FS may be attached on the carrier substrate 800 by an oxide-oxide bonding process, but the scope of the present disclosure is not limited thereto.

After inverting the worksheet, the preliminary substrate 700 may be removed, and the circuit structure DS may be formed by forming the substrate 110 including the base patterns 112. However, the circuit structure DS may be formed by performing a thinning process of removing a portion of the preliminary substrate 700, and it is not limited thereto.

In some embodiments, the substrate 110 may be an insulating substrate including an insulating material. In embodiments, the substrate 110 may include a silicon substrate and a buffer layer including an insulating material. In this case, the buffer layer may be interposed between the silicon substrate and the device gate electrode 142. In embodiments, the substrate 110 may include a silicon substrate and an insulating layer including an insulating material. In this case, the substrate 110 may form insulating layers in regions overlapping the device source/drain patterns 152, 154 in the first direction D1, and a space between the insulating layers may include the silicon substrate.

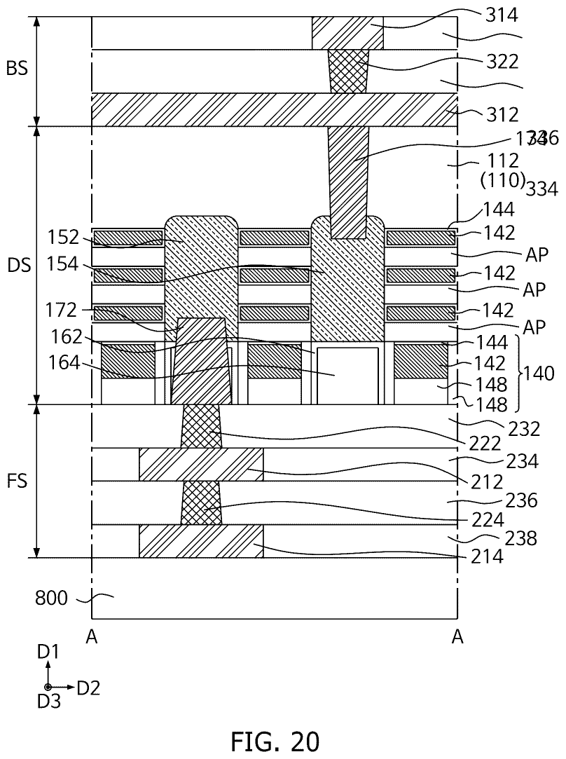

Referring to FIG. 20, the lower device contact 174 may be formed inside the substrate 110 by penetrating a backside of the circuit structure DS.

The backside device wiring structure BS may be formed on a backside of the substrate 110 (e.g., a backside of the circuit structure DS). For example, a first backside device inter-wiring insulating film may be formed, and the first backside device wiring pattern 312 may be formed in the first backside device inter-wiring insulating film. Also, a second backside device inter-wiring insulating film 334 may be formed on the first backside device inter-wiring insulating film, and the first backside device via pattern 322 connected to the first backside device wiring pattern 312 may be formed in the second backside device inter-wiring insulating film 334. Also, a third backside device inter-wiring insulating film 336 may be formed on the second backside device inter-wiring insulating film 334, and the second backside device wiring pattern 314 connected to the first backside device via pattern 322 may be formed in the third backside device inter-wiring insulating film 336. Through this, the backside device wiring structure BS may be formed.

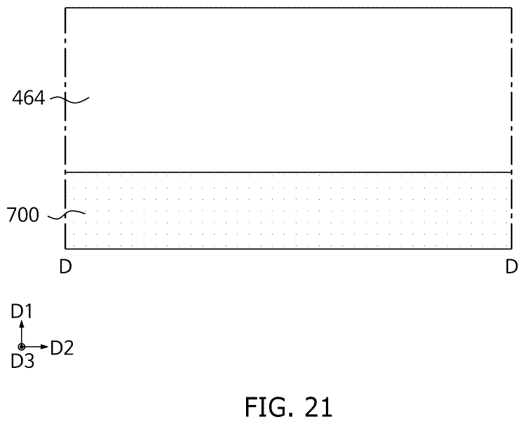

FIGS. 21 to 24 are diagrams for explaining a method of manufacturing a guard structure according to some embodiments. FIGS. 21 to 24 are diagrams corresponding to a cross-sectional view taken along line D-D of FIG. 6.

Referring to FIG. 21, a preliminary substrate 700 including a central region (e.g., a region corresponding to the central region of the substrate 110) and a peripheral region surrounding the central region (e.g., a region corresponding to the peripheral region of the substrate 110) may be provided. The guard interlayer insulating film 464 may be formed in the peripheral region of the preliminary substrate 700.

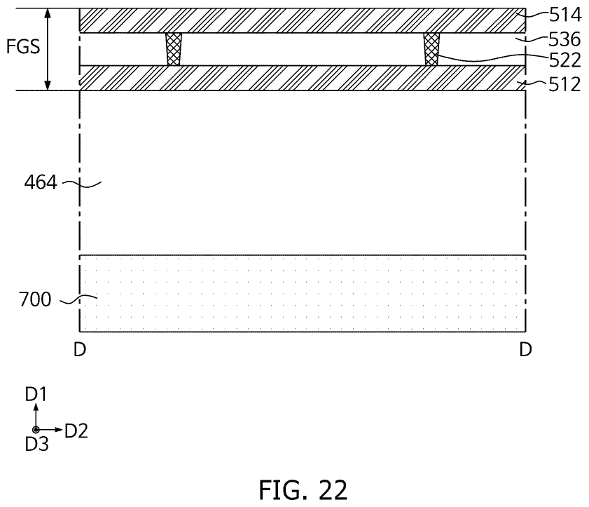

Referring to FIG. 22, the frontside guard wiring structure FGS may be formed on the guard interlayer insulating film 464.

For example, a first frontside guard inter-wiring insulating film may be formed on the guard interlayer insulating film 464. The first frontside guard wiring pattern 512 may be formed in the first frontside guard inter-wiring insulating film.

A second frontside guard inter-wiring insulating film 536 may be formed on the first frontside guard inter-wiring insulating film. The frontside guard via pattern 522 connected to the first frontside guard wiring pattern 512 may be formed in the second frontside guard inter-wiring insulating film 536.

A third frontside guard inter-wiring insulating film may be formed on the second frontside guard inter-wiring insulating film 536. The second frontside guard wiring pattern 514 connected to the frontside guard via pattern 522 may be formed in the third frontside guard inter-wiring insulating film.

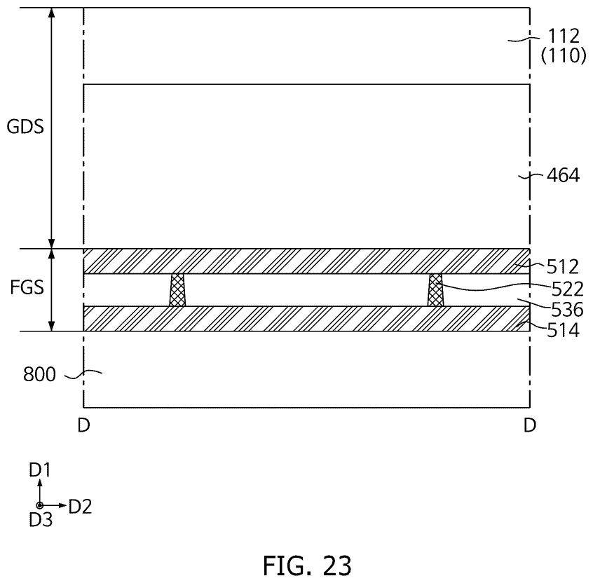

Referring to FIG. 23, the frontside guard wiring structure FGS may be attached on a carrier substrate 800. For example, a worksheet on which the manufacturing method of FIG. 22 has been performed may be inverted and attached so that a frontside of the frontside guard wiring structure FGS and a frontside of the carrier substrate 800 face one another. In some embodiments, the frontside guard wiring structure FGS may be attached on the carrier substrate 800 by an oxide-oxide bonding process, but the scope of the present disclosure is not limited thereto.

After inverting the worksheet, the preliminary substrate 700 may be removed, and the guard structure GDS may be formed by forming the substrate 110 including the base patterns 112.

In some embodiments, the substrate 110 may be an insulating substrate including an insulating material. In embodiments, the substrate 110 may include a silicon substrate and a buffer layer including an insulating material. In this case, the buffer layer may be interposed between the silicon substrate and the guard interlayer insulating film 464.

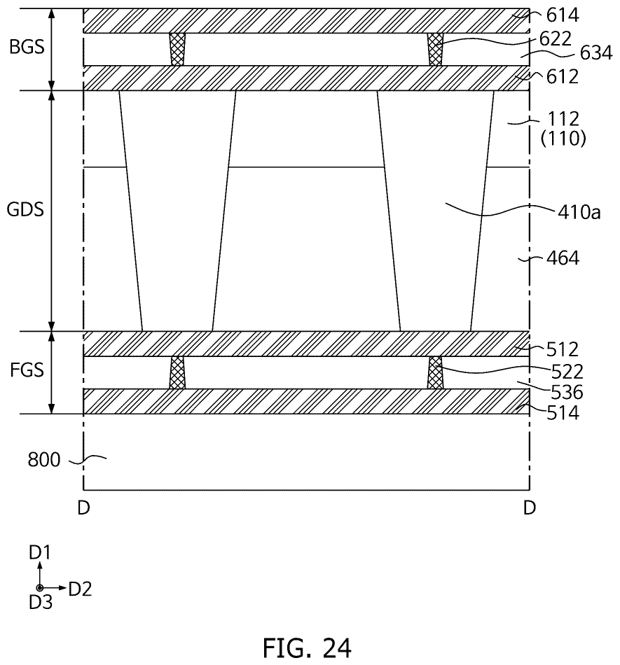

Referring to FIG. 24, the connection via pattern 410a may be formed by penetrating a backside of the guard structure GDS. For example, the connection via pattern 410a may be formed by penetrating the backside of the guard structure GDS, the substrate 110, and the guard interlayer insulating film 464.

The backside guard wiring structure BGS may be formed on a backside of the substrate 110 (e.g., a backside of the guard structure GDS). For example, a first backside guard inter-wiring insulating film may be formed, and the first backside guard wiring pattern 612 may be formed in the first backside guard inter-wiring insulating film. Also, a second backside guard inter-wiring insulating film 634 may be formed on the first backside guard inter-wiring insulating film, and a first backside guard via pattern 622 connected to the first backside guard wiring pattern 612 may be formed in the second backside guard inter-wiring insulating film 634. Also, a third backside guard inter-wiring insulating film may be formed on the second backside guard inter-wiring insulating film 634, and a second backside guard wiring pattern 614 connected to a second backside guard via pattern 622 may be formed in the third backside guard inter-wiring insulating film. Through this, the backside guard wiring structure BGS may be formed.

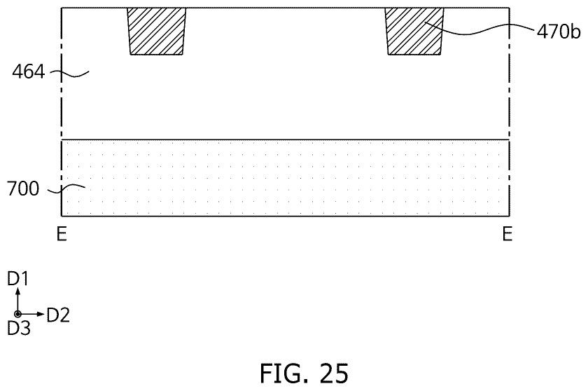

FIGS. 25 to 28 are diagrams for explaining a method of manufacturing a guard structure according to some embodiments. FIGS. 25 to 28 are diagrams corresponding to a cross-sectional view taken along line E-E of FIG. 8.

Referring to FIG. 25, a preliminary substrate 700 including a central region (e.g., a region corresponding to the central region of the substrate 110) and a peripheral region surrounding the central region (e.g., a region corresponding to the peripheral region of the substrate 110) may be provided. The guard interlayer insulating film 464 may be formed in the peripheral region of the preliminary substrate 700.

The upper contact 470b may be formed by penetrating a frontside of the guard interlayer insulating film 464.

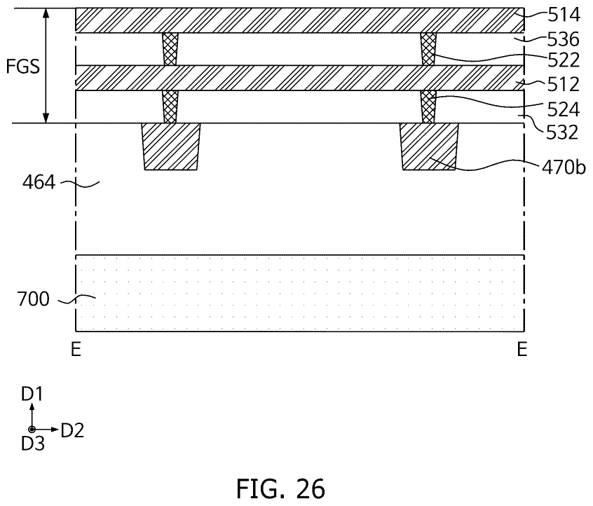

Referring to FIG. 26, the frontside guard wiring structure FGS may be formed on the guard interlayer insulating film 464.

For example, a first frontside guard inter-wiring insulating film 532 may be formed on the guard interlayer insulating film 464. A first frontside guard via pattern 524 connected to the upper contact 470b may be formed in the first frontside guard inter-wiring insulating film 532.

A second frontside guard inter-wiring insulating film may be formed on the first frontside guard inter-wiring insulating film 532. The first frontside guard wiring pattern 512 connected to the first frontside guard via pattern 524 may be formed in the second frontside guard inter-wiring insulating film.

A third frontside guard inter-wiring insulating film 536 may be formed on the second frontside guard inter-wiring insulating film. The second frontside guard via pattern 522 connected to the first frontside guard wiring pattern 512 may be formed in the third frontside guard inter-wiring insulating film 536.

A fourth frontside guard inter-wiring insulating film may be formed on the third frontside guard inter-wiring insulating film 536. The second frontside guard wiring pattern 514 connected to the second frontside guard via pattern 522 may be formed in the fourth frontside guard inter-wiring insulating film.

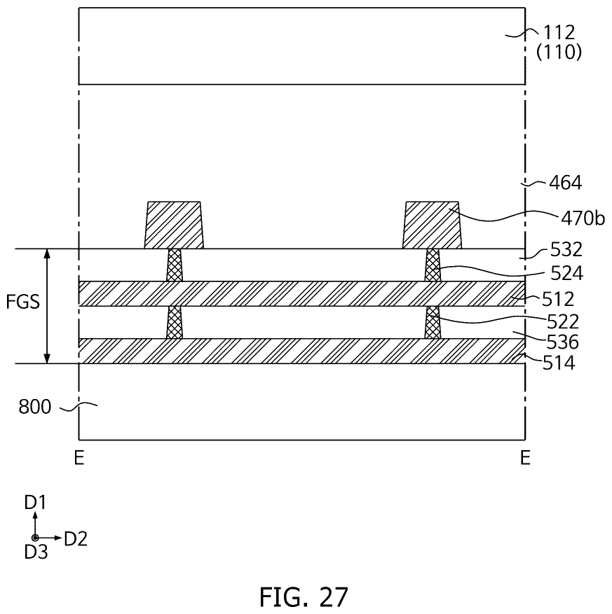

Referring to FIG. 27, the frontside guard wiring structure FGS may be attached on a carrier substrate 800. For example, a worksheet on which the manufacturing method of FIG. 26 has been performed may be inverted and attached so that a frontside of the frontside guard wiring structure FGS and a frontside of the carrier substrate 800 face one another. Embodiments for the manufacturing method of FIG. 27 and the material of the substrate 110 after attaching the frontside guard wiring structure FGS may correspond to embodiments for the manufacturing method of FIG. 23 and the material of the substrate 110.

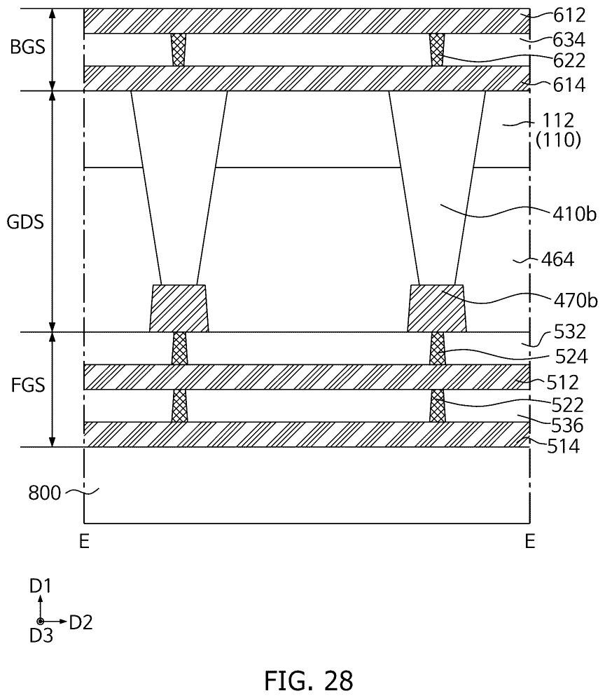

Referring to FIG. 28, the connection via pattern 410b may be formed by penetrating a backside of the guard structure GDS. For example, the connection via pattern 410b may be formed by penetrating the backside of the guard structure GDS, the substrate 110, and the guard interlayer insulating film 464. The connection via pattern 410b may be connected to the upper contact 470b.

The backside guard wiring structure BGS may be formed on a backside of the substrate 110 (e.g., a backside of the guard structure GDS). The manufacturing method of FIG. 28 for this may correspond to the manufacturing method of FIG. 24.

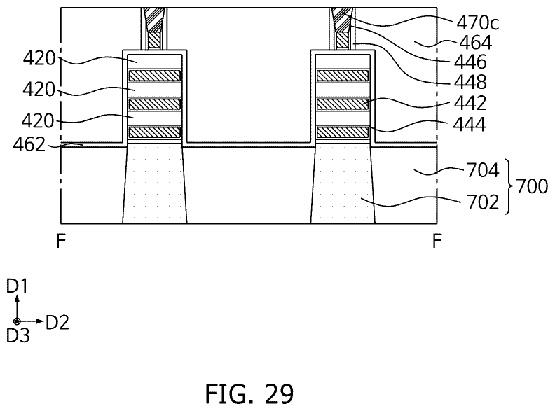

FIGS. 29 to 32 are diagrams for explaining a method of manufacturing a guard structure according to some embodiments. FIGS. 29 to 32 are diagrams corresponding to a cross-sectional view taken along line F-F of FIG. 10.

Referring to FIG. 29, a preliminary substrate 700 including a central region (e.g., a region corresponding to the central region of the substrate 110) and a peripheral region surrounding the central region (e.g., a region corresponding to the peripheral region of the substrate 110) may be provided. The plurality of semiconductor layers 420, the guard gate electrode 442, the guard gate insulating film 444, the guard gate capping film 446, the guard gate spacer 448, the guard gate etch stop film 462, and the guard interlayer insulating film 464 may be formed in the peripheral region of the preliminary substrate 700.

The peripheral region of the preliminary substrate 700 may include a first portion 702 and a second portion 704. The first portion 702 may overlap with the plurality of semiconductor layers 420, the guard gate electrode 442, the guard gate insulating film 444, the guard gate capping film 446, and the guard gate spacer 448 in the first direction D1.

The first portion 702 may include silicon. Alternatively, the first portion 702 may include another material, for example, silicon germanium (SiGe), silicon germanium on insulator (SGOI), indium antimonide, lead telluride compound, indium arsenide, indium phosphide, gallium arsenide, or gallium antimonide, but is not limited thereto.

The second portion 704 may include, for example, at least one of silicon oxide, silicon nitride, silicon oxycarbide, silicon oxynitride, silicon oxycarbonitride, and a combination thereof, but is not limited thereto.

The upper contact 470c may be formed by penetrating a frontside of the guard gate capping film 446.

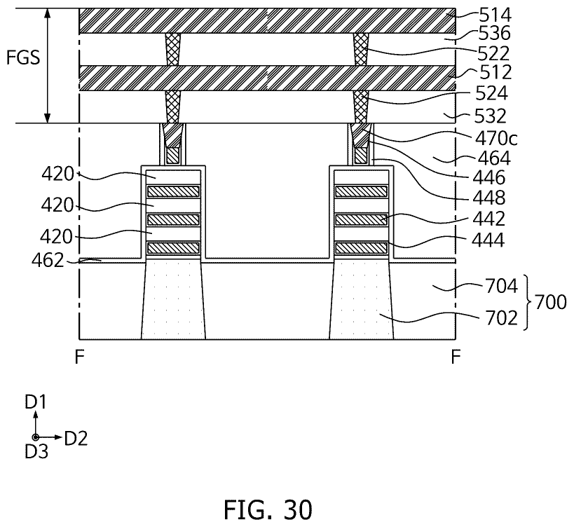

Referring to FIG. 30, the frontside guard wiring structure FGS may be formed on the guard interlayer insulating film 464. The manufacturing method of FIG. 30 for this may correspond to the manufacturing method of FIG. 26, except that the first frontside guard via pattern 524 is connected to the upper contact 470c connected to the guard gate electrode 442.

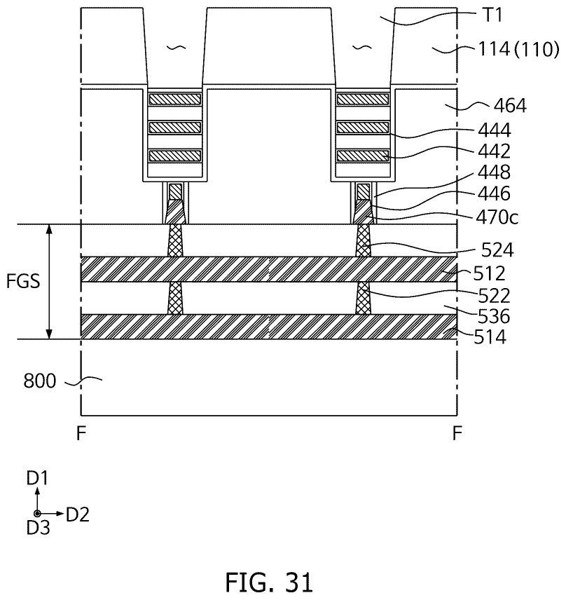

Referring to FIG. 31, the frontside guard wiring structure FGS may be attached on a carrier substrate 800. For example, a worksheet on which the manufacturing method of FIG. 30 has been performed may be inverted and attached so that a frontside of the frontside guard wiring structure FGS and a frontside of the carrier substrate 800 face one another. The first portion 702 may be removed, and a first trench T1 for forming the connection via pattern 410c may be formed. The second portion 704 may correspond to the field insulating film 114 of FIGS. 11 and 12.

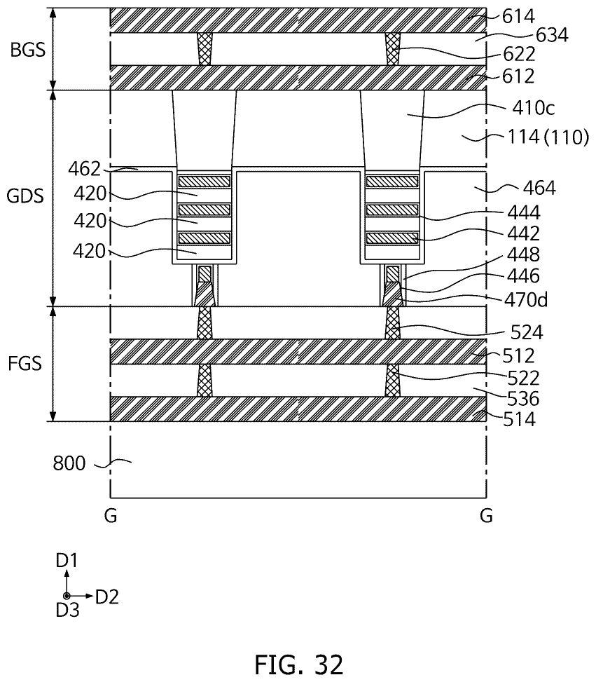

Referring to FIG. 32, the connection via pattern 410c may be formed inside the first trench T1. For example, the connection via pattern 410c may be connected to a semiconductor layer 420 adjacent to a backside of the guard structure GDS among the plurality of semiconductor layers 420.

The backside guard wiring structure BGS may be formed on a backside of the substrate 110 (e.g., a backside of the guard structure GDS). The manufacturing method of FIG. 32 for this may correspond to the manufacturing method of FIG. 28.

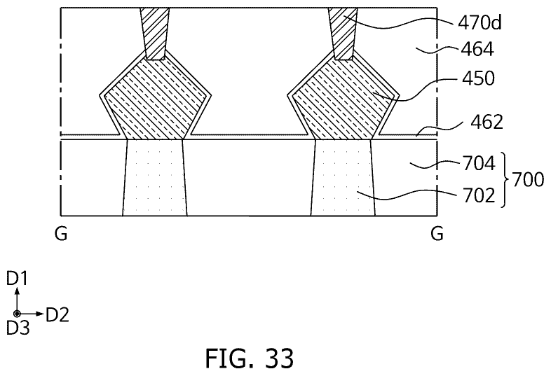

FIGS. 33 to 36 are diagrams for explaining a method of manufacturing a guard structure according to some embodiments. FIGS. 33 to 36 are diagrams corresponding to a cross-sectional view taken along line G-G of FIG. 10.

Referring to FIG. 33, a preliminary substrate 700 including a central region (e.g., a region corresponding to the central region of the substrate 110) and a peripheral region surrounding the central region (e.g., a region corresponding to the peripheral region of the substrate 110) may be provided. The guard source/drain pattern 450, the guard gate etch stop film 462, and the guard interlayer insulating film 464 may be formed in the peripheral region of the preliminary substrate 700.

The peripheral region of the preliminary substrate 700 may include a first portion 702 and a second portion 704. The first portion 702 may overlap with the guard source/drain pattern 450, the guard gate etch stop film 462, and the guard interlayer insulating film 464 in the first direction D1. A description of the materials of the first portion 702 and the second portion 704 may be the same as or similar to the description with reference to FIG. 29.

The upper contact 470d may be formed by penetrating a frontside of the guard interlayer insulating film 464.

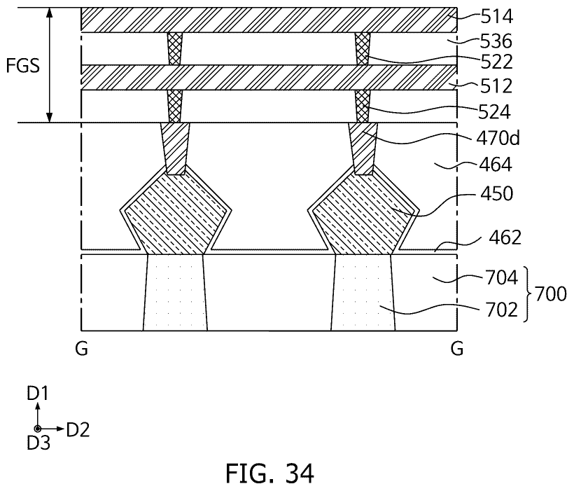

Referring to FIG. 34, the frontside guard wiring structure FGS may be formed on the guard interlayer insulating film 464. The manufacturing method of FIG. 30 for this may correspond to the manufacturing method of FIG. 26, except that the first frontside guard via pattern 524 is connected to the upper contact 470d connected to the guard source/drain pattern 450.

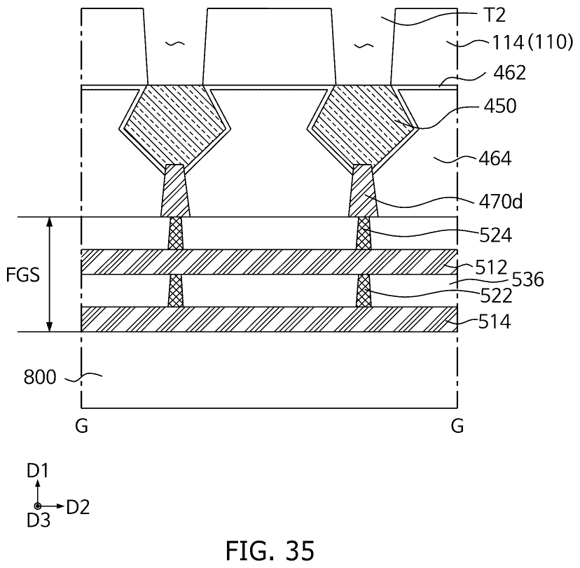

Referring to FIG. 35, the frontside guard wiring structure FGS may be attached on a carrier substrate 800. For example, a worksheet on which the manufacturing method of FIG. 34 has been performed may be inverted and attached so that a frontside of the frontside guard wiring structure FGS and a frontside of the carrier substrate 800 face one another. The first portion 702 may be removed, and a second trench T2 for forming the connection via pattern 410d may be formed. The second portion 704 may correspond to the field insulating film 114 of FIGS. 11 and 12.

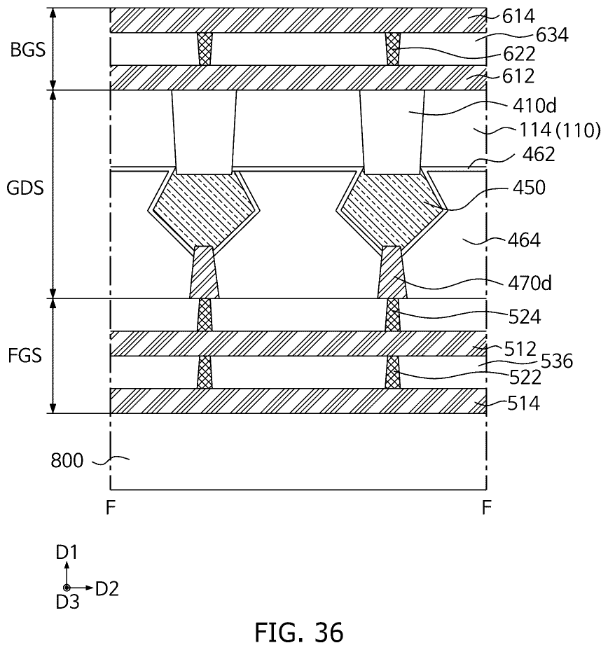

Referring to FIG. 36, the connection via pattern 410d may be formed inside the second trench T2. For example, the connection via pattern 410d may be connected to the guard source/drain pattern 450.

The backside guard wiring structure BGS may be formed on a backside of the substrate 110 (e.g., a backside of the guard structure GDS). The manufacturing method of FIG. 36 for this may correspond to the manufacturing method of FIG. 28.

The present disclosure is not limited by the above-described embodiments and the accompanying drawings, and various forms of substitution, modification, and change may be made by a person of ordinary skill in the art to which the present disclosure pertains without departing from the technical spirit of the present disclosure, and these will also fall within the scope of the present disclosure.

Specific configurations or features disclosed in the present specification, even if described as separate embodiments, may be implemented as a single embodiment, and conversely, configurations or features described as a single embodiment may be separated into two or more and implemented independently or in an appropriate combination. Also, even if specific configurations are described in a specific combination, in some cases, some configurations may be omitted or replaced with a combination with other configurations, and such changes should be understood to be included in the scope of the present disclosure.

What is claimed is:

1. A semiconductor device, comprising:
a substrate including a central region and a peripheral region surrounding the central region;
a guard structure disposed in the peripheral region and including a first surface and a second surface opposite to the first surface;
a frontside guard wiring structure disposed on the first surface of the guard structure; and
a backside guard wiring structure disposed on the second surface of the guard structure,
wherein:
the guard structure comprises a connection via pattern connected to the backside guard wiring structure and extending in a first direction substantially perpendicular to a surface of the substrate by penetrating the substrate, and
a first width of the connection via pattern at a first vertical level is greater than a second width of the connection via pattern at a second vertical level more adjacent to the frontside guard wiring structure than the first vertical level.

2. The semiconductor device as claimed in claim 1, wherein the connection via pattern is directly connected to the backside guard wiring structure and the frontside guard wiring structure.

3. The semiconductor device as claimed in claim 1, wherein:
the guard structure further includes an upper contact directly connected to the frontside guard wiring structure, and
a first width of the upper contact at a third vertical level is less than a second width of the upper contact at a fourth vertical level more adjacent to the frontside guard wiring structure than the third vertical level.

4. The semiconductor device as claimed in claim 3, wherein the connection via pattern is directly connected to the backside guard wiring structure and the upper contact.

5. The semiconductor device as claimed in claim 3, wherein the guard structure further comprises:
a plurality of semiconductor layers stacked on a surface of the substrate while being spaced apart from one another in the first direction; and
a guard gate electrode surrounding each of the plurality of semiconductor layers.

6. The semiconductor device as claimed in claim 5, wherein:
the upper contact is directly connected to the guard gate electrode, and
the connection via pattern is directly connected to a lowermost semiconductor layer of the plurality of semiconductor layers.

7. The semiconductor device as claimed in claim 3, wherein:
the guard structure further comprises a guard source/drain pattern disposed on the substrate,
the upper contact is directly connected to an upper portion of the guard source/drain pattern, and
the connection via pattern is directly connected to a lower portion of the guard source/drain pattern.

8. The semiconductor device as claimed in claim 1, wherein the connection via pattern includes a ring structure surrounding the central region from a planar point of view.

9. The semiconductor device as claimed in claim 1, wherein the connection via pattern is arranged in a zigzag shape along the peripheral region.

10. The semiconductor device as claimed in claim 1, wherein the frontside guard wiring structure comprises:
a first frontside guard wiring pattern extending in a second direction substantially parallel to the substrate;
a second frontside guard wiring pattern spaced apart from the first frontside guard wiring pattern in the first direction and extending in the second direction; and
a frontside guard via pattern connecting the first frontside guard wiring pattern and the second frontside guard wiring pattern, and
a first width of the frontside guard via pattern at a third vertical level is less than a second width of the frontside guard via pattern at a fourth vertical level farther from the guard structure than the third vertical level.

11. The semiconductor device as claimed in claim 10, wherein the frontside guard via pattern is a ring structure surrounding the central region from a planar point of view.

12. The semiconductor device as claimed in claim 10, wherein the frontside guard via pattern is arranged in a zigzag shape along the peripheral region.

13. The semiconductor device as claimed in claim 1, wherein the backside guard wiring structure comprises:
a first backside guard wiring pattern extending in a second direction substantially parallel to the substrate;
a second backside guard wiring pattern spaced apart from the first backside guard wiring pattern in the first direction and extending in the second direction; and
a backside guard via pattern connecting the first backside guard wiring pattern and the second backside guard wiring pattern, and
wherein a first width of the backside guard via pattern at a third vertical level is greater than a second width of the backside guard via pattern at a fourth vertical level more adjacent to the guard structure than the third vertical level.

14. The semiconductor device as claimed in claim 13, wherein the backside guard via pattern is a ring structure surrounding the central region from a planar point of view.

15. The semiconductor device as claimed in claim 13, wherein the backside guard via pattern is arranged in a zigzag shape along the peripheral region.

16. The semiconductor device as claimed in claim 1, further comprising:
a circuit structure disposed in the central region and including a first surface and a second surface opposite to the first surface;
a frontside device wiring structure disposed on the first surface of the circuit structure; and
a backside device wiring structure disposed on the second surface of the circuit structure,
wherein the circuit structure comprises:
an active pattern protruding in the first direction on a surface of the substrate and extending in a second direction substantially parallel to the substrate;
a device gate electrode disposed on the active pattern; and
a device gate contact connected to the device gate electrode and the frontside device wiring structure, and
wherein a first width of the device gate contact at a third vertical level is less than a second width of the device gate electrode at a fourth vertical level more adjacent to the frontside device wiring structure than the third vertical level.

17. The semiconductor device as claimed in claim 16, wherein the circuit structure further comprises:
a source/drain pattern disposed on a side surface of the active pattern; and
a lower device contact connected to the backside device wiring structure and the source/drain pattern, and
wherein a first width of the lower device contact at a third vertical level is greater than a second width of the lower device contact at a fourth vertical level farther from the backside device wiring structure than the third vertical level.

18. The semiconductor device as claimed in claim 16, wherein the circuit structure further comprises:
a source/drain pattern disposed on a side surface of the active pattern; and
an upper device contact connected to the frontside device wiring structure and the source/drain pattern, and
wherein a first width of the upper device contact at a third vertical level is less than a second width of the upper device contact at a fourth vertical level more adjacent to the frontside device wiring structure than the third vertical level.

19. A semiconductor device, comprising:
a substrate including a central region and a peripheral region surrounding the central region;
a guard structure disposed in the peripheral region and including a first surface and a second surface opposite to the first surface;
a frontside guard wiring structure disposed on the first surface of the guard structure; and
a backside guard wiring structure disposed on the second surface of the guard structure,
wherein:
the guard structure comprises a connection via pattern connected to the backside guard wiring structure and the frontside guard wiring structure,
the connection via pattern is a closed-type structure arranged in a zigzag shape having a plurality of bent portions along the peripheral region from a planar point of view, and
a first width of the connection via pattern at a first vertical level is greater than a second width of the connection via pattern at a second vertical level more adjacent to the frontside guard wiring structure than the first vertical level.

20. A semiconductor device, comprising:
a substrate including a central region and a peripheral region surrounding the central region;
a guard structure disposed in the peripheral region and including a first surface and a second surface opposite to the first surface;
a frontside guard wiring structure disposed on the first surface of the guard structure; and
a backside guard wiring structure disposed on the second surface of the guard structure,
wherein the frontside guard wiring structure comprises:
a first frontside guard wiring pattern disposed on the first surface of the guard structure and extending in a first direction substantially parallel to the first surface;
a second frontside guard wiring pattern spaced apart from the first frontside guard wiring pattern in a second direction intersecting the first direction; and
a frontside guard via pattern connecting the first frontside guard wiring pattern and the second frontside guard wiring pattern,
the backside guard wiring structure comprises:
a first backside guard wiring pattern disposed on the second surface of the guard structure and extending in the first direction;
a second backside guard wiring pattern spaced apart from the first backside guard wiring pattern in the second direction; and
a backside guard via pattern connecting the first backside guard wiring pattern and the second backside guard wiring pattern,
wherein the guard structure includes a connection via pattern connected to the backside guard wiring structure and the frontside guard wiring structure,
a first width of the connection via pattern at a first vertical level is greater than a second width of the connection via pattern at a second vertical level more adjacent to the frontside guard wiring structure than the first vertical level,
a first width of the frontside guard via pattern at a third vertical level is less than a second width of the frontside guard via pattern at a fourth vertical level farther from the guard structure than the third vertical level, and
a first width of the backside guard via pattern at a fifth vertical level is greater than a second width of the backside guard via pattern at a sixth vertical level more adjacent to the guard structure than the fifth vertical level.
